(19) United States
(12) Patent Application Publication
(10) Pub. No.: US 2025/0362777 A1
(43) Pub. Date: Nov. 27, 2025

(54) DISPLAY DEVICE, ELECTRONIC DEVICE INCLUDING THE SAME, AND METHOD FOR MANUFACTURING THE DISPLAY DEVICE

(71) Applicant: Samsung Display Co., Ltd., Yongin-si (KR)

(72) Inventors: BEOMSOO PARK, Yongin-si (KR); IN-BAE KIM, Yongin-si (KR); Eunji LIM, Yongin-si (KR); JIRYUN PARK, Yongin-si (KR); JAEIK LIM, Yongin-si (KR)

(21) Appl. No.: 19/075,405

(22) Filed: Mar. 10, 2025

(30) Foreign Application Priority Data
May 21, 2024 (KR) 10-2024-0065972
Sep. 11, 2024 (KR) 10-2024-0124161

(51) Int. Cl. G06F 3/044; H10H 29/85; H10H 29/852; H10K 59/40; H10K 77/10; H10K 102/00

(52) U.S. Cl. CPC G06F 3/0445; H10H 29/8517; H10H 29/852; H10K 59/40; G06F 2203/04103; H10K 77/111; H10K 2102/311

(57) ABSTRACT

A display device includes: a display panel including a plurality of pixels; and an input sensor on the display panel, wherein the input sensor includes: a first sensor insulating layer on the display panel; a sensor conductive layer on the first sensor insulating layer and including a plurality of conductive patterns; a second sensor insulating layer configured to cover each of the plurality of conductive patterns and including an organic material; and a protective layer on the second sensor insulating layer and including an inorganic material.

### CROSS-REFERENCE TO RELATED APPLICATION

The present application claims priority to and the benefit of Korean Patent Application No. 10-2024-0065972, filed on May 21, 2024, and Korean Patent Application No. 10-2024-0124161, filed on Sep. 11, 2024, in the Korean Intellectual Property Office, the entire disclosures of each of which are incorporated herein by reference.

### BACKGROUND

Aspects of some embodiments of the present disclosure herein relate to a display device, an electronic device and a method for manufacturing the same.

Multimedia apparatuses such as televisions, mobile phones, tablet computers, navigation units, and game consoles, include display devices that provide images for users through display screens. The display devices may include display panels, which generate the images, and input sensors, which detect the users' touch.

The input sensors may include conductors, which detect external inputs, and the conductors of the input sensors located on the display panels may affect light-emission efficiency of the display devices or external light reflectance of the display devices.

The above information disclosed in this Background section is only for enhancement of understanding of the background and therefore the information discussed in this Background section does not necessarily constitute prior art.

### SUMMARY

Aspects of some embodiments of the present disclosure herein relate to a display device, an electronic device and a method for manufacturing the same, and for example, to a display device with relatively improved durability and impact resistance characteristics.

Aspects of some embodiments of the present disclosure include a display device with relatively improved durability and impact resistance characteristics, and a method for manufacturing the display device.

According to some embodiments of the present disclosure, a display device includes: a display panel including a plurality of pixels, and an input sensor on the display panel. According to some embodiments, the input sensor includes a first sensor insulating layer on the display panel, a sensor conductive layer on the first sensor insulating layer and including a plurality of conductive patterns, a second sensor insulating layer which covers each of the plurality of conductive patterns and includes an organic material, and a protective layer on the second sensor insulating layer and including an inorganic material.

According to some embodiments, the input sensor may further include an intermediate sensor insulating layer which covers at least a portion of the sensor conductive layer.

According to some embodiments, the sensor conductive layer may include a first sensor conductive layer on the first sensor insulating layer and including a plurality of first sensor conductive patterns, and a second sensor conductive layer on the intermediate sensor insulating layer and including a plurality of second sensor conductive patterns.

According to some embodiments, the protective layer may cover each of the plurality of second sensor conductive patterns.

According to some embodiments, the intermediate sensor insulating layer may include an inorganic material.

According to some embodiments, the intermediate sensor insulating layer may include an organic material.

According to some embodiments, the display panel may include a first non-folding area, a folding area, and a second non-folding area which are arranged in sequence in one direction.

According to some embodiments, the second sensor insulating layer may include a melamine resin.

According to some embodiments, a thickness of the second sensor insulating layer may be about 2.5 times to about 4.5 times a thickness of the sensor conductive layer.

According to some embodiments, the display device may further include an anti-reflective layer on the input sensor and including a plurality of color filters and a planarization layer which covers the plurality of color filters.

According to some embodiments, the planarization layer may include the same material as the second sensor insulating layer.

According to some embodiments, the sensor conductive layer may be provided as a single layer. According to some embodiments, the second sensor insulating layer may be directly on the sensor conductive layer.

According to some embodiments, the display panel may include a display area in which the plurality of pixels are located, and a peripheral area adjacent to the display area. According to some embodiments, the peripheral area may include a pad area in which a plurality of pads are located, and the second sensor insulating layer may include a pad opening portion overlapping the pad area.

According to some embodiments, the display panel may include a first non-bending area, a bending area, and a second non-bending area which are arranged in sequence in one direction. According to some embodiments, the second sensor insulating layer may include a bending opening portion overlapping the bending area.

According to some embodiments, the display panel may include a pixel defining film in which an emission opening portion is defined, a light emitting element including at least an emission layer in the emission opening portion, and an encapsulation layer on the light emitting element and the pixel defining film. The first sensor insulating layer may be directly on the encapsulation layer.

According to some embodiments of the present disclosure, an electronic device includes a display panel including a plurality of pixels, an input sensor on the display panel, and a housing accommodates the display panel and the input sensor. According to some embodiments, the input sensor includes a first sensor insulating layer on the display panel, a sensor conductive layer on the first sensor insulating layer and including a plurality of conductive patterns, a second sensor insulating layer directly on the plurality of conductive patterns and including a low-temperature curable organic material, and a protective layer on the second sensor insulating layer.

According to some embodiments, a thickness of the second sensor insulating layer may be about 2.5 times to about 4.5 times a thickness of the sensor conductive layer.

According to some embodiments of the present disclosure, a method for manufacturing a display device includes preparing a display panel including a plurality of pixels, and forming an input sensor on the display panel. According to some embodiments, the forming of the input sensor includes forming a first sensor insulating layer on the display panel, forming, on the first sensor insulating layer, a sensor conductive layer including a plurality of conductive patterns, providing an organic composition so as to cover each of the plurality of conductive patterns, curing the organic composition to form a second sensor insulating layer, and depositing an inorganic material onto the second sensor insulating layer to form a protective layer.

According to some embodiments, the method for manufacturing the display device may further include forming, on the input sensor, an anti-reflective layer including a plurality of color filters and a planarization layer which covers the plurality of color filters. According to some embodiments, the planarization layer may be formed of the same material as the organic composition.

According to some embodiments, the curing of the organic composition may be performed at a temperature of about 100° C. or less.

### BRIEF DESCRIPTION OF THE DRAWINGS

The accompanying drawings are included to provide a further understanding of embodiments according to the present disclosure, and are incorporated in and constitute a part of this specification. The drawings illustrate embodiments of the inventive concept and, together with the description, serve to explain principles of the inventive concept. In the drawings:

FIGS. 1A to 1C are each a perspective view of an electronic apparatus according to some embodiments of the present disclosure;

FIG. 2A is an exploded perspective view of an electronic apparatus according to some embodiments of the present disclosure;

FIG. 2B is a block diagram of an electronic apparatus according to some embodiments of the present disclosure;

FIG. 3 is a plan view of a display panel according to some embodiments of the present disclosure;

FIG. 4 is a cross-sectional view of a display module according to some embodiments of the present disclosure;

FIG. 5 is a cross-sectional view of a portion of a display module according to some embodiments of the present disclosure;

FIG. 6 is a cross-sectional view of a display device according to some embodiments of the present disclosure;

FIG. 7 is a plan view of an input sensor according to some embodiments of the present disclosure;

FIGS. 8A to 8D are each a cross-sectional view of an input sensor according to some embodiments of the present disclosure;

FIG. 9 is a plan view of a portion of a display panel according to some embodiments of the present disclosure;

FIG. 10 is a cross-sectional view of some components of a display device according to some embodiments of the present disclosure;

FIG. 11A is a flowchart of a method for manufacturing a display device according to some embodiments of the present disclosure;

FIG. 11B is a flowchart of some steps of a method for manufacturing a display device according to some embodiments of the present disclosure; and

FIGS. 12A to 12D are cross-sectional views of some steps of a method for manufacturing a display device according to some embodiments of the present disclosure.

### DETAILED DESCRIPTION

In the present disclosure, it will be understood that when an element (or region, layer, section, etc.) is referred to as being “on”, “connected to” or “coupled to” another element, it can be located directly on, connected or coupled to the other element or a third element may be located between the elements.

As used herein, “being directly located” may mean that there is no additional layer, film, region, plate or the like between a part such as a layer, film, region, plate or the like and another part. For example, “being directly located” may mean that two layers or two members are arranged with no additional member such as an adhesive member.

Like reference numbers or symbols refer to like elements throughout. In addition, in the drawings, the thickness, the ratio, and the dimension of elements are exaggerated for effective description of the technical contents. The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present invention, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to the accompanying drawings.

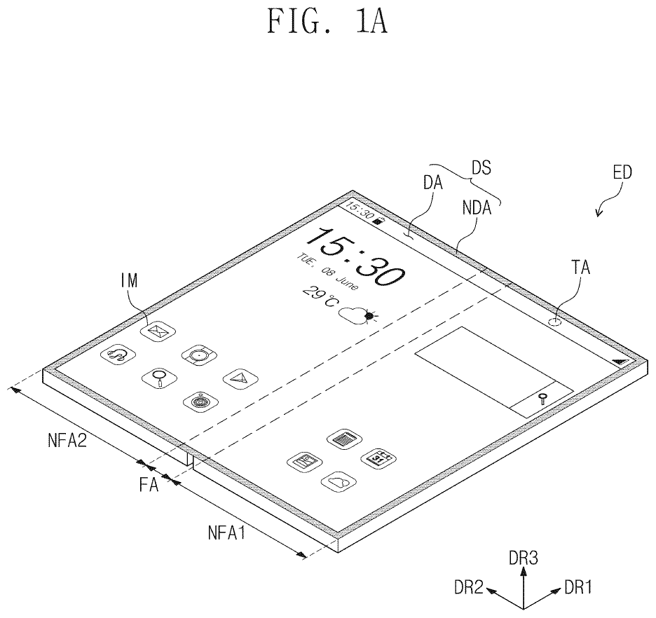

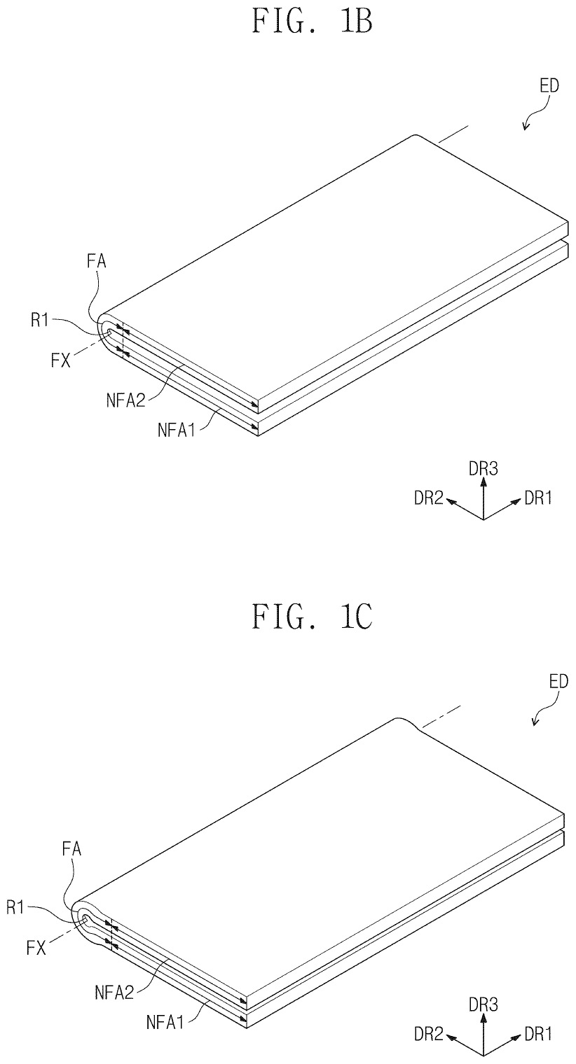

FIGS. 1A to 1C are each a perspective view of an electronic apparatus according to some embodiments of the present disclosure. FIG. 1A illustrates an unfolded state, and FIGS. 1B and 1C illustrate folded states.

Referring to FIGS. 1A to 1C, an electronic apparatus ED according to some embodiments of the present disclosure may include a display surface DS defined by a first direction DR1 and a second direction DR2 crossing the first direction DR1. The electronic apparatus ED may provide an image IM for a user through the display surface DS.

The display surface DS may include a display area DA and a non-display area NDA around (e.g., in a periphery or outside a footprint of) the display area DA. The display area DA may display the image IM, and the non-display area NDA may not display the image IM. The non-display area NDA may surround (e.g., in a periphery or outside a footprint of) the display area DA. However, embodiments of the present disclosure are not limited thereto, and a shape of the display area DA and a shape of the non-display area NDA may be changed.

The display surface DS may include a sensing area TA. The sensing area TA may be a partial area of the display area DA. The sensing area TA has a higher transmittance than the other area of the display area DA. Hereinafter, the other area of the display area DA except for the sensing area TA may be defined as a general display area.

A light signal, for example, visible light or infrared light, may travel to the sensing area TA. The electronic apparatus ED may photograph an external image using visible light passing through the sensing area TA, or may determine approach of an external object using infrared light. As an example, FIG. 1A illustrates one sensing area TA. However, embodiments of the present disclosure are not limited thereto, and the sensing area TA may be provided in plurality.

Hereinafter, a direction perpendicularly (or substantially perpendicularly) crossing a plane defined by the first direction DR1 and the second direction DR2 is defined as a third direction DR3. The third direction DR3 serves as a basis for distinguishing a front surface and a rear surface of each member. The term “on a plane” or “in a plan view” used herein may be defined as a state being when viewed from the third direction DR3 toward the electronic apparatus ED. Hereinafter, the first to third directions DR1, DR2 and DR3 are directions indicated by first to third directional axes, respectively, and are designated by like reference numbers or symbols.

The electronic apparatus ED may include a folding area FA and a plurality of non-folding areas NFA1 and NFA2. The non-folding areas NFA1 and NFA2 may include a first non-folding area NFA1 and a second non-folding area NFA2. The folding area FA may be located between the first non-folding area NFA1 and the second non-folding area NFA2 in the second direction DR2.

As illustrated in FIG. 1B, the folding area FA may be folded around a folding axis FX parallel to the first direction DR1. The folding area FA has a curvature (e.g., a set or predetermined curvature) and a radius of curvature (e.g., a set or predetermined radius of curvature) R1. The first non-folding area NFA1 and the second non-folding area NFA2 may face each other, and the electronic apparatus ED may be inner-folded so that the display surface DS is not exposed to the outside.

According to some embodiments of the present disclosure, the electronic apparatus ED may be outer-folded so that the display surface DS is exposed to the outside. According to some embodiments of the present disclosure, the electronic apparatus ED may be provided to repeat an operation from an unfolding operation to an inner-folding or outer-folding operation, or vice versa, but is not limited thereto. According to some embodiments of the present disclosure, the electronic apparatus ED may be provided so as to select any one among the unfolding operation, the inner-folding operation, and the outer-folding operation.

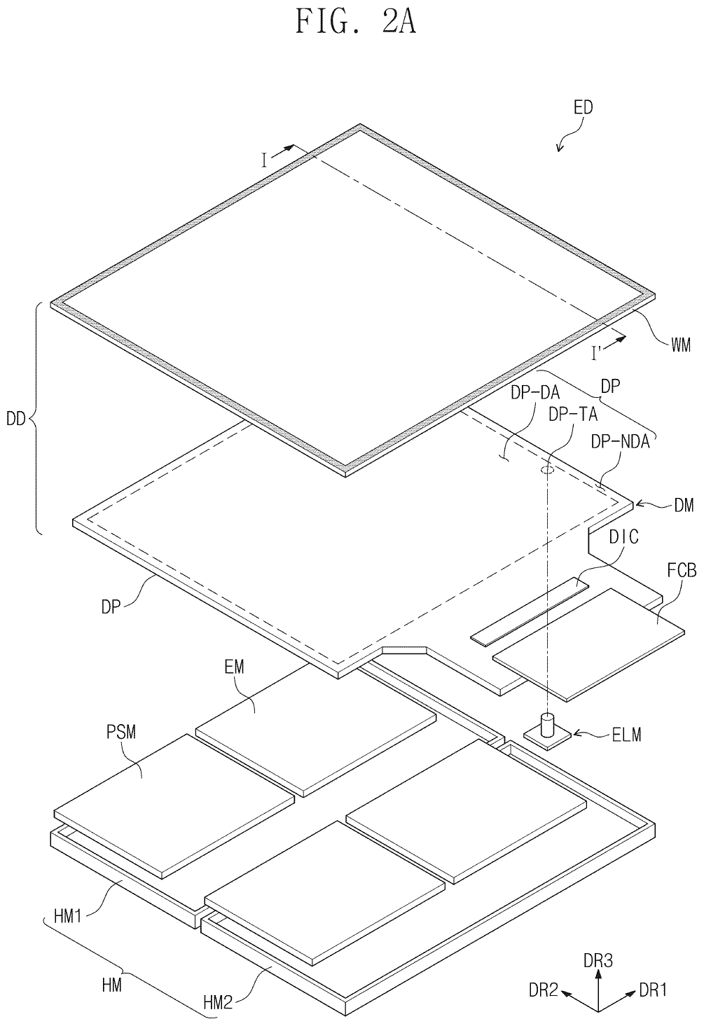

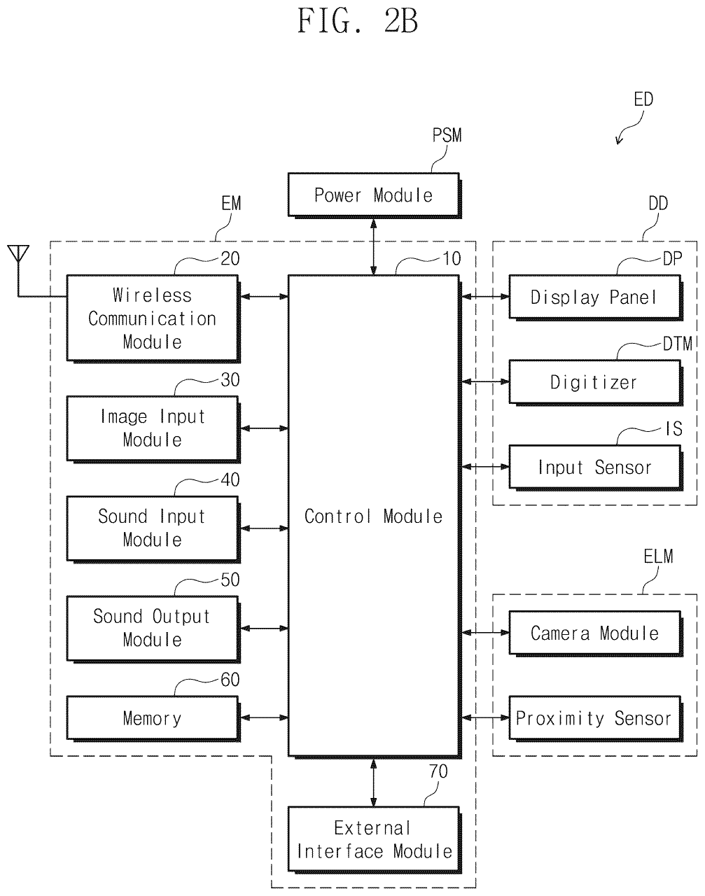

As illustrated in FIG. 1B, a distance between the first non-folding area NFA1 and the second non-folding area NFA2 may be the same (or substantially the same) as the radius of curvature R1, or alternatively, as illustrated in FIG. 1C, the distance between the first non-folding area NFA1 and the second non-folding area NFA2 may be less than the radius of curvature R1. FIGS. 1B and 1C are views illustrated based on the display surface DS, and housings HM (see FIG. 2A) constituting an outer appearance of the electronic apparatus ED may be in contact with each other in an end area of the first non-folding area NFA1 and the second non-folding area NFA2.

FIG. 2A is an exploded perspective view of an electronic apparatus according to some embodiments of the present disclosure. FIG. 2B is a block diagram of an electronic apparatus according to some embodiments of the present disclosure.

As illustrated in FIGS. 2A and 2B, an electronic apparatus ED may include a display device DD, an electronic module EM, an electro-optical module ELM, a power module PSM, and a housing HM. According to some embodiments, the electronic apparatus ED may further include a mechanical structure for controlling a folding operation of the display device DD.

The display device DD generates an image and detects an external input. The display device DD includes a window WM and a display module DM. The window WM provides a front surface of the electronic apparatus ED. The window WM will be described later in detail.

The display module DM may include at least a display panel DP. FIG. 2A illustrates only the display panel DP of a stacked structure of the display module DM, but the display module DM may further include a plurality of components located above the display panel DP. The stacked structure of the display module DM will be described later in detail.

The display panel DP is not particularly limited, and may be an emissive display panel, for example, an organic light emitting display panel or a quantum dot light emitting display layer. The display panel DP may be a display panel including an ultra-small light emitting element such as a micro LED or a nano LED.

The display panel DP includes a display area DP-DA and a non-display area DP-NDA corresponding to the display area DA (see FIG. 1A) and the non-display area NDA (see FIG. 1A) of the electronic apparatus ED, respectively. In the present disclosure, when “a region/portion correspond to another region/portion”, it means that the regions/portions overlap each other, and is not limited to the meaning that the regions/portions have the same surface area.

The display panel DP may include a sensing area DP-TA corresponding to the sensing area TA in FIG. 1A. The sensing area DP-TA may be an area having a lower resolution than the display area DP-DA. The sensing area DP-TA will be described later in detail.

As illustrated in FIG. 2A, a driving chip DIC may be located on the non-display area DP-NDA of the display panel DP. A flexible circuit board FCB may be coupled to the non-display area DP-NDA of the display panel DP. The flexible circuit board FCB may be connected to a main circuit board. The main circuit board may be one electronic component constituting the electronic module EM.

The driving chip DIC may include driving elements, for example, a data driving circuit, for driving pixels of the display panel DP. FIG. 2A illustrates a structure in which the driving chip DIC is mounted on the display panel DP, but embodiments of the present disclosure are not limited thereto. For example, the driving chip DIC may be mounted on the flexible circuit board FCB.

As illustrated in FIG. 2B, the display device DD may further include an input sensor IS and a digitizer DTM. The input sensor IS detects a user's input. The input sensor IS that is a capacitance type may be located above the display panel DP. The digitizer DTM detects an input of a stylus pen. The digitizer DTM that is an electromagnetic induction-type may be located below the display panel DP.

The electronic module EM may include a control module 10, a wireless communication module 20, an image input module 30, a sound input module 40, a sound output module 50, a memory 60, an external interface module 70, and the like. The electronic module EM may include a main circuit board, and the foregoing modules may be mounted on the main circuit board, or electrically connected to the main circuit board through a flexible circuit board. The electronic module EM is electrically connected to the power module PSM.

Referring to FIG. 2B, the electronic module EM may be located in each of a first housing HM1 and a second housing HM2, and the power module PSM may be located in each of the first housing HM1 and the second housing HM2. According to some embodiments, the electronic module EM located in the first housing HM1 and the electronic module EM located in the second housing HM2 may be electrically connected to each other through the flexible circuit board.

The control module 10 controls the overall operation of the electronic apparatus ED. For example, the control module 10 activates or inactivates the display device DD to conform to a user's input. The control module 10 may control the image input module 30, the sound input module 40, the sound output module 50, and the like, to conform to the user's input. The control module 10 may include at least one microprocessor.

The wireless communication module 20 may transmit/receive a wireless signal to/from another terminal using a Bluetooth or WiFi channel. The wireless communication module 20 may transmit/receive an audio signal using a general communication channel. The wireless communication module 20 may include a plurality of antenna modules.

The image input module 30 processes an image signal and converts the image signal to image data displayable on the display device DD. The sound input module 40 receives an external sound signal through a microphone in a recording mode, an audio recognition mode, or the like, and converts the external audio signal to an electronic audio data. The sound output module 50 converts sound data received from the wireless communication module 20, or sound data stored in the memory 60, and outputs the converted sound data to the outside.

The external interface module 70 serves as an interface connected to an external charger, a wired/wireless data port, a card socket (e.g., a memory card and a SIM/UIM card), or the like.

The power module PSM supplies power required for the overall operation of the electronic apparatus ED. The power module PSM may include a general battery device.

The electro-optical module ELM may be an electronic component that outputs or receives an optical signal. The electro-optical module ELM may include a camera module and/or a proximity sensor. The camera module photographs an external image through the sensing area DP-TA.

The housing HM illustrated in FIG. 2A is coupled to the display device DD, particularly to the window WM, and accommodates the other modules above. The housing HM is illustrated as including the first and second housings HM1 and HM2 separated from each other, but is not limited thereto. According to some embodiments, the electronic apparatus ED may further include a hinge structure for connecting the first and second housings HM1 and HM2 to each other.

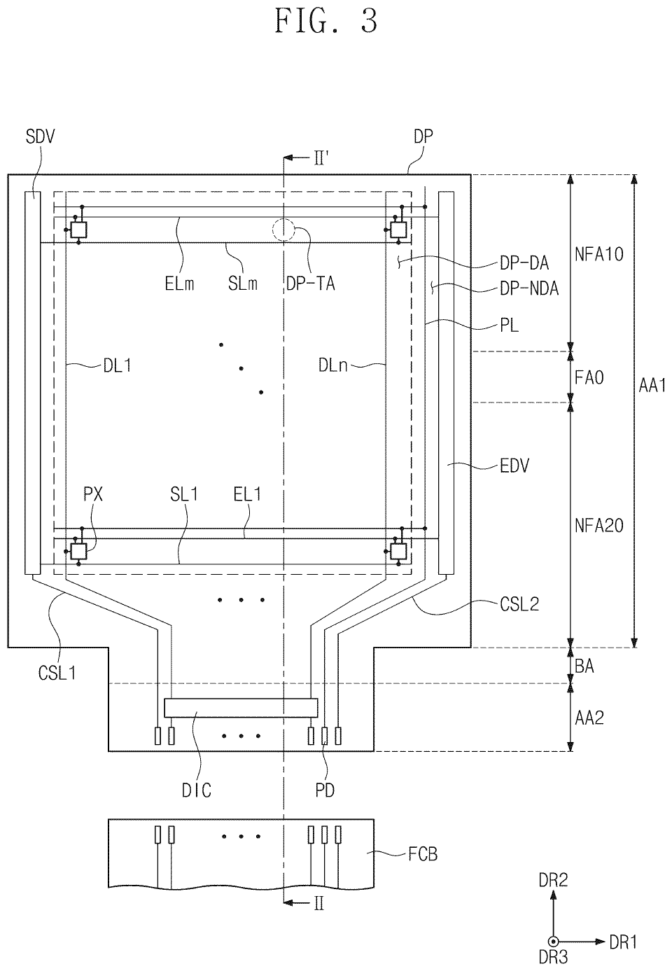

FIG. 3 is a plan view of a display panel according to some embodiments of the present disclosure.

Referring to FIG. 3, a display panel DP may include a display area DP-DA and a non-display area DP-NDA around the display area DP-DA. The display area DP-DA and the non-display area DP-NDA may be divided according to whether a pixel PX is present or not. The pixel PX is located in the display area DP-DA. A scan driver SDV, a data driver, and an emission driver EDV may be located in the non-display area DP-NDA. The data driver may be a partial circuit included in a driving chip DIC illustrated in FIG. 3.

The display panel DP includes a first area AA1, a second area AA2, and a bending area BA which are divided in the second direction DR2. The second area AA2 and the bending area BA may be a partial area of the non-display area DP-NDA. The bending area BA may be located between the first area AA1 and the second area AA2.

The first area AA1 is an area corresponding to the display surface DS in FIG. 1A. The first area AA1 may include a first non-folding area NFA10, a second non-folding area NFA20, and a folding area FA0. The first non-folding area NFA10, the second non-folding area NFA20, and the folding area FA0 correspond to the first non-folding area NFA1, the second non-folding area NFA2, and the folding area FA, respectively, which are illustrated in FIGS. 1A to 1C.

In the first direction DR1, a length of each of the bending area BA and the second area AA2 may be less than a length of the first area AA1. An area having a smaller length in a bending-axis direction may be more easily bent.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, and a plurality of pads PD. Here, m and n are each a natural number. The pixels PX may be connected to the scan lines SL1 to SLm, the data lines DL1 to DLn, and the emission lines EL1 to ELm.

The scan lines SL1 to SLm may extend in the second direction DR2 to be connected to the scan driver SDV. The data lines DL1 to DLn may extend in the second direction DR2 and be connected to the driving chip DIC via the bending area BA. The emission lines EL1 to ELm may extend in the first direction DR1 to be connected to the emission driver EDV.

The power line PL may include a portion extending in the second direction DR2 and a portion extending in the first direction DR1. The portion extending in the first direction DR1 and the portion extending in the second direction DR2 may be located on different layers. The portion, which extends in the second direction DR2, of the power line PL may extend to the second area AA2 via the bending area BA. The power line PL may supply a first voltage to the pixels PX.

A first control line CSL1 may be connected to the scan driver SDV and extend toward a lower end of the second area AA2 via the bending area BA. A second control line CSL2 may be connected to the emission driver EDV and extend toward the lower end of the second area AA2 via the bending area BA.

The pads PD may be located adjacent to the lower end of the second area AA2 on a plane. The driving chip DIC, the power line PL, the first control line CSL1, and the second control line CSL2 may be connected to the pads PD. A flexible circuit board FCB may be electrically connected to the pads PD through an anisotropic conductive adhesive layer.

A sensing area DP-TA may be an area having a higher light transmittance and a lower resolution than the display area DP-DA. The light transmittance and the resolution are measured in a reference surface area. The sensing area DP-TA has a smaller occupation rate of a light blocking structure in the reference surface area than the display area DP-DA. The light blocking structure may include a conductive pattern of a circuit layer, an electrode of a light emitting element, a light blocking pattern, etc., which will be described later.

The sensing area DP-TA has a lower resolution in the reference surface area than the display area DP-DA. The sensing area DP-TA may be an area on which a smaller number of pixels PX are located in the reference surface area (or the same surface area) compared to the display area DP-DA. The sensing area DP-TA may be an area through which that an optical signal passes.

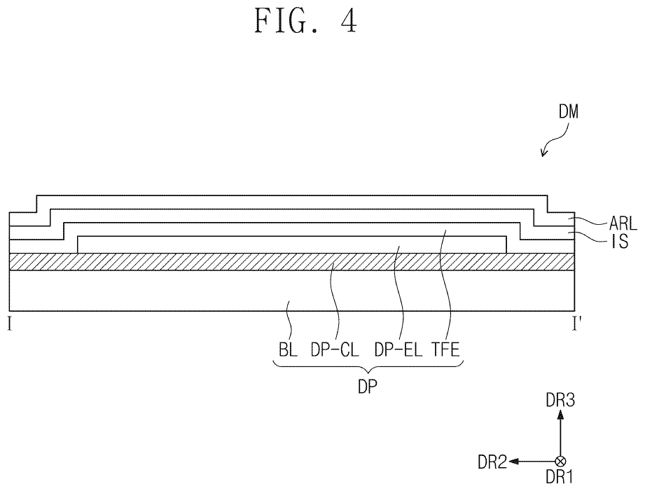

FIG. 4 is a cross-sectional view of a display module according to some embodiments of the present disclosure. FIG. 4 illustrates a cross-section of a display module DM corresponding to line I-I′ in FIG. 2A.

Referring to FIG. 4, the display module DM may include a display panel DP, an input sensor IS, and an anti-reflective layer ARL. The display panel DP may include a base layer BL, a circuit layer DP-CL, a light emitting element layer DP-EL, and an encapsulation layer TFE.

The base layer BL may provide a base surface on which the circuit layer DP-CL is located. The base layer BL may be a flexible substrate capable of bending, folding, rolling, or the like. The base layer BL may be a glass substrate, a metal substrate, a polymer substrate, or the like. However, embodiments of the present disclosure are not limited thereto, and the base layer BL may be an inorganic layer, an organic layer, or a composite material layer.

The base layer BL may have a multilayer structure. For example, the base layer BL may include a first synthetic resin layer, an inorganic layer having a multilayer or single-layer structure, and a second synthetic resin layer located on the inorganic layer having the multilayer or single-layer structure. The first and second synthetic resin layers each may include a polyimide-based resin, and are not particularly limited.

The circuit layer DP-CL may be located on the base layer BL. The circuit layer DP-CL may include an insulating layer, a semiconductor pattern, a conductive pattern, a signal line, and the like.

The light emitting element layer DP-EL may be located on the circuit layer DP-CL. The light emitting element layer DP-EL may include a light emitting element. For example, the light emitting element may include an organic light emitting material, an inorganic light emitting material, an organic-inorganic light emitting material, a quantum dot, a quantum rod, a micro LED, or a nano LED.

The encapsulation layer TFE may be located on the light emitting element layer DP-EL. The encapsulation layer TFE may protect the light emitting element layer DP-EL from moisture, oxygen, and foreign matter such as dust particles. The encapsulation layer TFE may include at least one inorganic layer. The encapsulation layer TFE may include a stacked structure of inorganic layer/organic layer/inorganic layer.

The input sensor IS may be directly located on the display panel DP. The display panel DP and the input sensor IS may be formed through a continuous process. Here, “being directly located” may mean that a third component is not located between the input sensor IS and the display panel DP. That is, a separate adhesive layer may not be located between the input sensor IS and the display panel DP.

The anti-reflective layer ARL may be directly located on the input sensor IS. The anti-reflective layer ARL may reduce reflectance of external light incident from the outside of the display device DD. The anti-reflective layer ARL may include color filters. The color filters may have an arrangement (e.g., a set or predetermined arrangement) or curvature. For example, the color filters may be arranged considering emissive colors of pixels included in the display panel DP. In addition, the anti-reflective layer ARL may further include a black matrix adjacent to the color filters.

According to some embodiments of the present disclosure, respective positions of the sensor layer IS and the anti-reflective layer ARL may be exchanged. According to some embodiments of the present disclosure, the anti-reflective layer ARL may be replaced with a polarizing film. The polarizing film may be coupled to the input sensor IS through an adhesive layer.

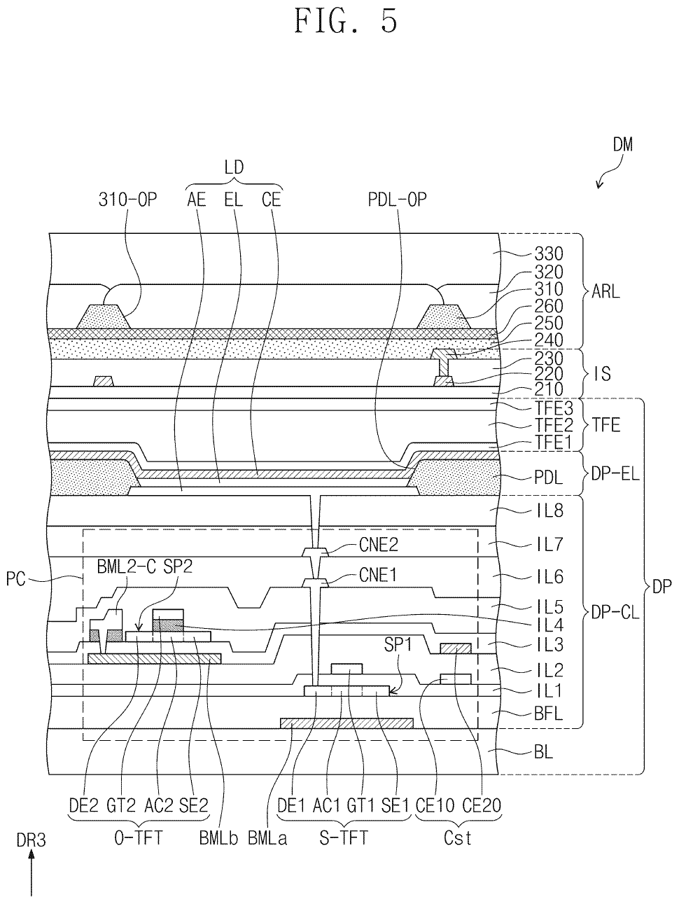

FIG. 5 is a cross-sectional view of a portion of a display module according to some embodiments of the present disclosure. In FIG. 5A, a portion of the display module DM according to the embodiments illustrated in FIG. 4 is illustrated in more detail. For example, in FIG. 5, components corresponding one pixel of the display module DM according to some embodiments are illustrated in more detail.

FIG. 5 illustrates one light emitting element LD, and a silicon transistor S-TFT and an oxide transistor O-TFT of a pixel circuit PC. At least one of a plurality of transistors included in the pixel circuit PC may be the oxide transistor O-TFT, and the remaining transistors may each be the silicon transistor S-TFT.

A buffer layer BFL may be located on a base layer BL. The buffer layer BFL may prevent or reduce instances of a phenomenon in which metal atoms or impurities spread from the base layer BL to a first semiconductor pattern SP1 above the buffer layer BFL. The first semiconductor pattern SP1 includes an active region AC1 of the silicon transistor S-TFT. The buffer layer BFL may adjust a heat supply rate during a crystallization process for forming the first semiconductor pattern SP1 so that the first semiconductor pattern SP1 is uniformly formed.

A first rear metal layer BMLa may be located below the silicon transistor S-TFT, and a second rear metal layer BMLb may be located below the oxide transistor O-TFT. The first and second rear metal layers BMLa and BMLb may be arranged to overlap the pixel circuit PC. The first and second rear metal layers BMLa and BMLb may prevent or reduce external light reaching the pixel circuit PC.

The first rear metal layer BMLa may be arranged to correspond to at least a partial area of the pixel circuit PC. The first rear metal layer BMLa may be arranged so as to overlap a driving transistor embodied as the silicon transistor S-TFT.

The first rear metal layer BMLa may be located between the base layer BL and the buffer layer BFL. According to some embodiments of the present disclosure, an inorganic barrier layer may be further located between the first rear metal layer BMLa and the buffer layer BFL. The first rear metal layer BMLa may be connected to an electrode or a line, and may receive a constant voltage or a signal from the electrode and the line. According to some embodiments of the present disclosure, the first rear metal layer BMLa may be a floating electrode having a shape isolated from another electrode or line.

The second rear metal layer BMLb may be arranged to correspond to a lower portion of the oxide transistor O-TFT. The second rear metal layer BMLb may be located between a second insulating layer IL2 and a third insulating layer IL3. The second rear metal layer BMLb may be located on the same layer as a second electrode CE20 of a storage capacitor Cst. The second rear metal layer BMLb may be connected to a contact electrode BML2-C and receive a constant voltage or a signal. The contact electrode BML2-C may be located on the same layer as a gate GT2 of the oxide transistor O-TFT.

Each of the first rear metal layer BMLa and the second rear metal layer BMLb may include a reflective metal. For example, each of the first rear metal layer BMLa and the second rear metal layer BMLb may include silver (Ag), silver (Ag)-containing alloy, molybdenum (Mo), molybdenum-containing alloy, aluminum (AI), aluminum-containing alloy, aluminum nitride (AlN), tungsten (W), tungsten nitride (WN), copper (Cu), a p+ doped amorphous silicon, and the like. The first rear metal layer BMLa and the second rear metal layer BMLb may include the same material, or may include different materials.

According to some embodiments, according to some embodiments of present disclosure, the second rear metal layer BMLb may be omitted. The first rear metal layer BMLa may extend to below the oxide transistor O-TFT, and the first rear metal layer BMLa may block light incident from below the oxide transistor O-TFT.

The first semiconductor pattern SP1 may be located on the buffer layer BFL. The first semiconductor pattern SP1 may include a silicon semiconductor. For example, the silicon semiconductor may include an amorphous silicon, a polycrystalline silicon, or the like. For example, the first semiconductor pattern SP1 may include low-temperature polysilicon.

FIG. 5 just illustrates a portion of the first semiconductor pattern SP1 located on the buffer layer BFL, and the first semiconductor pattern SP1 may be further located in another area. The first semiconductor pattern SP1 may be arranged over pixels according to a specific rule. The first semiconductor pattern SP1 may have different electrical properties according to whether the first semiconductor pattern SP1 is doped or not. The first semiconductor pattern SP1 may include a first region with high conductivity and a second region with low conductivity. The first region may be doped with an n-type dopant or a p-type dopant. A p-type transistor may include a doped region doped with the p-type dopant, and an n-type transistor may include a doped region doped with the n-type dopant. The second region may be a non-doped region, or a region doped at a lower concentration than the first region.

The conductivity of the first region may be higher than the conductivity of the second region, and the first region may serve as an electrode or a signal line. The second region may correspond to an active region (or channel) of a transistor. In other words, one portion of the first semiconductor pattern SP1 may be an active region of the transistor, another portion thereof may be a source or a drain of the transistor, and still another portion thereof may be a connection electrode or a connection signal line.

A source region SE1 (or source), the active region AC1 (or channel), and a drain region DE1 (drain) of the silicon transistor S-TFT may be provided from the first semiconductor pattern SP1. The source region SE1 and the drain region DE1 may extend from the active region AC1 in opposite directions on a cross-section.

A first insulating layer IL1 may be located on the buffer layer BFL. The first insulating layer IL1 may overlap, in common, a plurality of pixels and cover the first semiconductor pattern SP1. The first insulating layer IL1 may be an inorganic layer and/or an organic layer, and have a single-layer or multilayer structure. The first insulating layer IL1 may include at least one of aluminum oxide, titanium oxide, silicon oxide, silicon nitride, silicon oxynitride, zirconium oxide, or hafnium oxide. According to some embodiments, the first insulating layer IL1 may be a silicon oxide layer having a single-layer structure. In addition to the first insulating layer IL1, an insulating layer of a circuit layer DP-CL to be described later may be an inorganic layer and/or an organic layer, and have a single-layer or multilayer structure. The inorganic layer may include at least one of the foregoing materials, but embodiments according to the present disclosure are not limited thereto.

A gate GT1 of the silicon transistor S-TFT is located on the first insulating layer IL1. The gate GT1 may be a portion of a metal pattern. The gate GT1 overlaps the active region AC1. The gate GT1 may function as a mask in a process of doping the first semiconductor pattern SP1. The gate GT1 may include titanium (Ti), silver (Ag), silver-containing alloy, molybdenum (Mo), molybdenum-containing alloy, aluminum (Al), aluminum-containing alloy, aluminum nitride (AlN), tungsten (W), tungsten nitride (WN), copper (Cu), indium tin oxide (ITO), indium zinc oxide (IZO), or the like, but is not particularly limited thereto.

The second insulating layer IL2 may be located on the first insulating layer IL1 and cover the gate GT1. The third insulating layer IL3 may be located on the second insulating layer IL2. The second electrode CE20 of the storage capacitor Cst may be located between the second insulating layer IL2 and the third insulating layer IL3. In addition, a first electrode CE10 of the storage capacitor Cst may be located between the first insulating layer IL1 and the second insulating layer IL2.

A second semiconductor pattern SP2 may be located on the third insulating layer IL3. The second semiconductor pattern SP2 may include an active region AC2 of the oxide transistor O-TFT to be described later. The second semiconductor pattern SP2 may include an oxide semiconductor. The second semiconductor pattern SP2 may include a transparent conductive oxide (TCO) such as indium tin oxide (ITO), indium zinc oxide (IZO), indium gallium zinc oxide (IGZO), zinc oxide (ZnO), or indium oxide (In₂O₃).

The oxide semiconductor may include a plurality of regions divided according to whether the transparent conductive oxide is reduced or not. A region in which the transparent conductive oxide is reduced (hereinafter referred to as a reduced region) has higher conductivity than a region in which the transparent conductive oxide is not reduced (hereinafter referred to as a non-reduced region). The reduced region serves as a signal line or a source/drain of a transistor. The non-reduced region corresponds to a semiconductor region (or active region or channel) of the transistor. In other words, a partial region of the second semiconductor pattern SP2 may be the semiconductor region of the transistor, another partial region thereof may be a source region/drain region of the transistor, and still another partial region thereof may be a signal transfer region.

A source region SE2 (or source), the active region AC2 (or channel), and a drain region DE2 (drain) of the oxide transistor O-TFT may be provided from the second semiconductor pattern SP2. The source region SE2 and the drain region DE2 may extend from the active region AC2 in opposite directions on a cross-section.

A fourth insulating layer IL4 may be located on the third insulating layer IL3. As illustrated in FIG. 5, the fourth insulating layer IL4 may be an insulating pattern that overlaps the gate GT2 of the oxide transistor O-TFT and exposes each of the source region SE2 and the drain region DE2 of the oxide transistor O-TFT. As illustrated in FIG. 5, the fourth insulating layer IL4 may cover the second semiconductor pattern SP2.

As illustrated in FIG. 5, the gate GT2 of the oxide transistor O-TFT is located on the fourth insulating layer IL4. The gate GT2 of the oxide transistor O-TFT may be a portion of a metal pattern. The gate GT2 of the oxide transistor O-TFT overlaps the active region AC2.

A fifth insulating layer IL5 may be located on the fourth insulating layer IL4 and cover the gate GT2. A first connection electrode CNE1 may be located on the fifth insulating layer IL5. The first connection electrode CNE1 may be connected to the drain region DE1 of the silicon transistor S-TFT through a contact hole passing through the first to fifth insulating layers IL1, IL2, IL3, IL4 and IL5.

A sixth insulating layer IL6 may be located on the fifth insulating layer IL5. A second connection electrode CNE2 may be located on the sixth insulating layer IL6. The second connection electrode CNE2 may be connected to the first connection electrode CNE1 through a contact hole passing through the sixth insulating layer IL6. A seventh insulating layer IL7 may be located on the sixth insulating layer IL6 and cover the second connection electrode CNE2. An eighth insulating layer IL8 may be located on the seventh insulating layer IL7.

Each of the sixth insulating layer IL6, the seventh insulating layer IL7, and the eighth insulating layer IL8 may be an organic layer. For example, each of the sixth insulating layer IL6, the seventh insulating layer IL7, and the eighth insulating layer IL8 may include a general purpose polymer such as benzocyclobutene (BCB), polyimide, hexamethyldisiloxane (HMDSO), polymethyl methacrylate (PMMA), or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, and the like.

The light emitting element LD may include a first electrode AE, an emission layer EL, and a second electrode CE. The second electrode CE may be provided, in common, on a plurality of light emitting elements.

The first electrode AE of the light emitting element LD may be located on the eighth insulating layer IL8. The first electrode AE of the light emitting element LD may be a (semi-) transmissive electrode or a reflective electrode. According to some embodiments of the present disclosure, the first electrode AE of the light emitting element LD may include a reflective layer made of Ag, Mg, Al, Pt, Pd, Au, Ni, Nd, Ir, Cr, a compound thereof, or the like, and a transparent or semi-transparent electrode layer provided on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode AE of the light emitting element LD may include a stacked structure of ITO/Ag/ITO.

A pixel defining film PDL may be located on the eighth insulating layer IL8. The pixel defining film PDL may have a light absorbing property, and for example, the pixel defining film PDL may have a black color. The pixel defining film PDL may include a black component (black coloring agent). The black component may include a black dye or a black pigment. The black component may include a carbon black, a metal such as chrome, or an oxide thereof. The pixel defining film PDL may correspond to a light blocking pattern having a light blocking property.

The pixel defining film PDL may cover a portion of the first electrode AE of the light emitting element LD. For example, an opening PDL-OP which exposes a portion of the first electrode AE of the light emitting element LD may be defined in the pixel defining film PDL. The pixel defining film PDL may increase a distance between the second electrode CE and an edge of the first electrode AE of the light emitting element LD. Thus, the pixel definition layer PDL may serve to prevent or reduce instances of an arc or the like occurring at the edge of the first electrode AE.

According to some embodiments, a hole control layer may be located between the first electrode AE and the emission layer EL. The hole control layer may include a hole transport layer, and further include a hole injection layer. An electron control layer may be located between the emission layer EL and the second electrode CE. The electron control layer may include an electron transport layer, and further include an electron injection layer. The hole control layer and the electron control layer may be provided, in common, in the plurality of pixels PX (see FIG. 3) by using an open mask.

An encapsulation layer TFE may be located on a light emitting element layer DP-EL. The encapsulation layer TFE may include an inorganic layer TFE1, an organic layer TFE2, and an inorganic layer TFE3 which are stacked in sequence, but layers constituting the encapsulation layer TFE are not limited thereto.

The inorganic layers TFE1 and TFE3 may protect the light emitting element layer DP-EL from moisture and oxygen, and the organic layer TFE2 may protect the light emitting element layer DP-EL from foreign matter such as dust particles. The inorganic layers TFE1 and TFE3 may include a silicon nitride layer, a silicon oxynitride layer, a silicon oxide layer, a titanium oxide layer, an aluminum oxide layer, or the like. The organic layer TFE2 may include an acryl-based organic layer, and is not limited thereto.

An input sensor IS may be located on the display panel DP. The input sensor IS may be referred to as a sensor, an input sensing layer, or an input sensing panel. The input sensor IS may include a first sensor insulating layer 210, a first sensor conductive layer 220, an intermediate sensor insulating layer 230, a second sensor conductive layer 240, a second sensor insulating layer 250, and a protective layer 260.

The first sensor insulating layer 210 may be directly located on a display panel DP. The first sensor insulating layer 210 may be an inorganic layer including at least one of silicon nitride, silicon oxynitride, or silicon oxide. Alternatively, the first sensor insulating layer 210 may be an organic layer including epoxy resin, acrylic resin, or imide-based resin. The first sensor insulating layer 210 may have a single-layer structure, or have a multilayer structure in which layers are stacked in the third direction DR3.

Each of the first sensor conductive layer 220 and the second sensor conductive layer 240 may have a single-layer structure, or have a multilayer structure in which layers are stacked in the third direction DR3. The first sensor conductive layer 220 and the second sensor conductive layer 240 may include conductive patterns that define a mesh-shaped sensing electrode. The conductive patterns may not overlap the opening PDL-OP but overlap the pixel defining film PDL.

The conductive layer having a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). In addition, the transparent conductive layer may include a conductive polymer such as PEDOT, metal nanowire, graphene, or the like.

The conductive layer having a multilayer structure may include metal layers stacked in sequence. The metal layers may have, for example, a three-layer structure of titanium/aluminum/titanium. The conductive layer having a multilayer structure may include at least one metal layer and at least one transparent conductive layer.

The intermediate sensor insulating layer 230 may be located between the first sensor conductive layer 220 and the second sensor conductive layer 240. The intermediate sensor insulating layer 230 may include an inorganic film. The inorganic film may include at least one of aluminum oxide, titanium oxide, silicon oxide, silicon nitride, silicon oxynitride, zirconium oxide, or hafnium oxide. Alternatively, the intermediate sensor insulating layer 230 may include an organic film. The organic film may include at least one of acryl-based resin, methacryl-based resin, polyisoprene, vinyl-based resin, epoxy-based resin, urethane-based resin, cellulose-based resin, siloxane-based resin, polyimide-based resin, polyamide-based resin, or perylene-based resin. Alternatively, the organic film may include a melamine resin.

The second sensor insulating layer 250 is located on the second sensor conductive layer 240. The second sensor insulating layer 250 may include an organic material, and be provided to have a thickness (e.g., a set or predetermined thickness) or greater and planarize upper portions of the conductive patterns of the conductive layer located below the second sensor insulating layer 250.

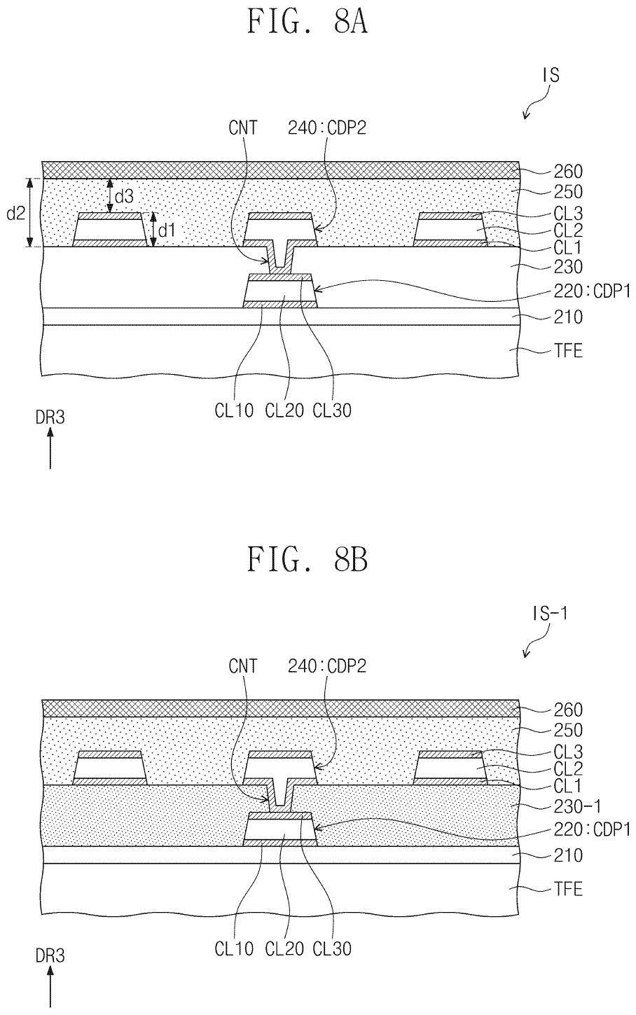

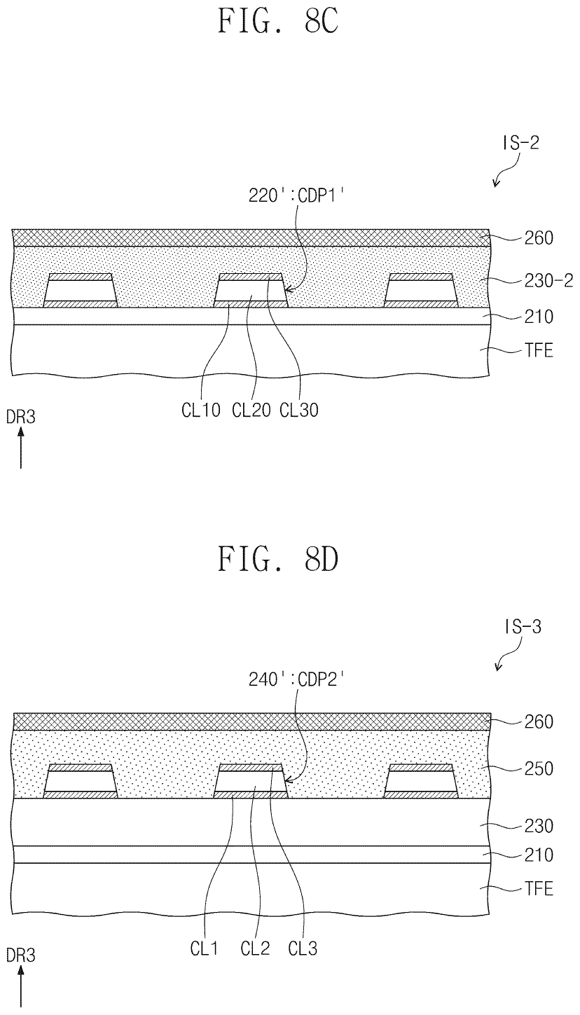

The protective layer 260 is located on the second sensor insulating layer 250. The protective layer 260 may include an inorganic material, protect the conductive patterns located therebelow from an external impact, and block moisture and oxygen. The second sensor insulating layer 250 and the protective layer 260 will be described later in detail with reference to FIG. 8A and the following drawings.

An anti-reflective layer ARL may be located on the input sensor IS. The anti-reflective layer ARL may include a division layer 310, a plurality of color filters 320, and a planarization layer 330.

A material constituting the division layer 310 is not particularly limited as long as being a material that absorbs light. The division layer 310 may be a layer having a black color, and according to some embodiments, the division layer 310 may include a black component (black coloring agent). The black component may include a black dye or a black pigment. The black component may include a carbon black, a metal such as chrome, or an oxide thereof.

The division layer 310 may prevent or reduce external light reflection due to the conductive patterns of the second sensor conductive layer 240 located below the division layer 310. The division layer 310 may omitted in a partial area of the display module DM. The area in which the division layer 310 is omitted and is not located may have a higher transmittance than the other area.

An opening 310-OP may be defined in the division layer 310. The opening 310-OP may overlap the first electrode AE of the light emitting element LD on a plane. Any one of the plurality of color filters 320 may overlap the first electrode AE of the light emitting element LD. Any one of the plurality of color filters 320 may cover the opening 310-OP. Each of the plurality of color filters 320 may be in contact with the division layer 310.

The planarization layer 330 may cover the division layer 310 and the plurality of color filters 320. The planarization layer 330 may include an organic material, and a flat surface may be provided on a top surface of the planarization layer 330. The planarization layer 330 may include the same material as the material included in the second sensor insulating layer 250. According to some embodiments of the present disclosure, the planarization layer 330 may be omitted.

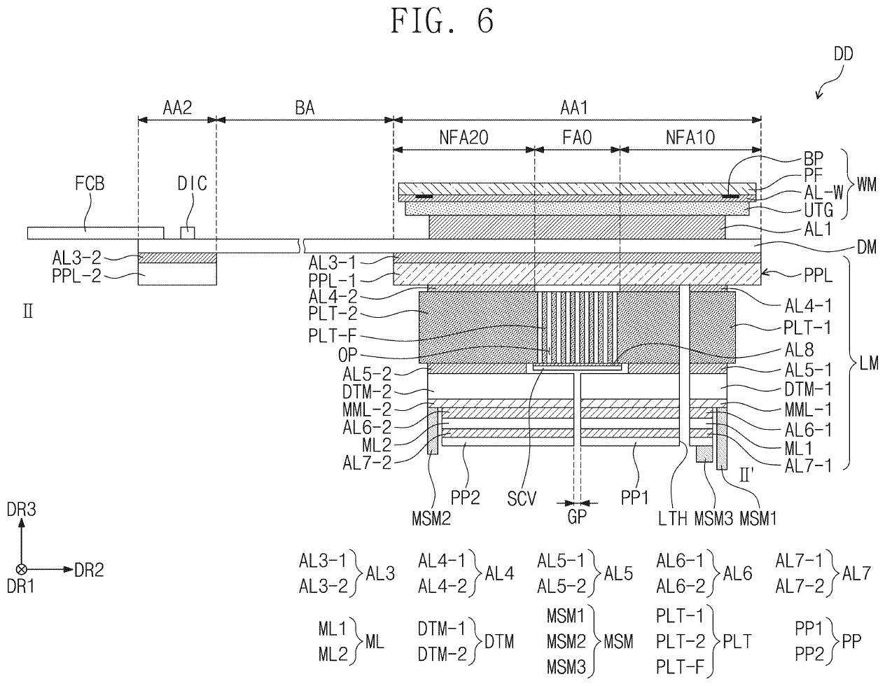

FIG. 6 is a cross-sectional view of a display device according to some embodiments of the present disclosure. FIG. 6 illustrates an unfolded state in which a display module DM is not bent. FIG. 6 illustrates a cross-section corresponding to line II-II′ in FIG. 3. In FIG. 6, areas which divide the display module DM are illustrated based on the display panel DP in FIG. 3.

Referring to FIG. 6, a display device DD includes a window WM, an upper member UM, the display module DM and a lower member LM. The upper member UM collectively refers to components located between the window WM and the display module DM, and the lower member LM collectively refers to components located below the display module DM.

The window WM may include a thin-film glass substrate UTG, a window protective layer PF located on the thin-film glass substrate UTG, and a bezel pattern BP located on a bottom surface of the window protective layer PF. According to some embodiments, the window protective layer PF may include a synthetic resin film. The window WM may include a window adhesive layer AL-W which couples the window protective layer PF and the thin-film glass substrate UTG to each other.

The bezel pattern BP overlaps the non-display area NDA illustrated in FIG. 1A. The bezel pattern BP may be located on one surface of the thin-film glass substrate UTG or one surface of the window protective layer PF. As an example, FIG. 6 illustrates the bezel pattern BP located on the bottom surface of the window protective layer PF. However, embodiments of the present disclosure are not limited thereto, and the bezel pattern BP may be located on a top surface of the window protective layer PF. The bezel pattern BP is a colored light-blocking film, and may be formed, for example, through coating. The bezel pattern BP may include a base material and a dye or pigment mixed with the base material.

The thin-film glass substrate UTG may have a thickness in a range of 15 micrometers to 45 micrometers (or about 15 micrometers to about 45 micrometers). The thickness of the thin-film glass substrate UTG may be, for example, 30 micrometers (or about 30 micrometers). The thin-film glass substrate UTG may be a chemically strengthened glass. The thin-film glass substrate UTG may minimize the occurrence of wrinkles even when folding and unfolding are repeated.

The window protective layer PF may have a thickness in a range of 50 micrometers to 80 micrometers (or about 50 micrometers to about 80 micrometers). A synthetic resin film of the window protective layer PF may include polyimide, polycarbonate, polyamide, triacetylcellulose, polymethylmethacrylate, or polyethylene terephthalate. According to some embodiments, at least one of a hard coating layer, an anti-fingerprint layer, or an anti-reflective layer may be located on the top surface of the window protective layer PF.

The window adhesive layer AL-W may be a pressure sensitive adhesive (PSA) film or an optically clear adhesive (OCA) member. Adhesive layers to be described below may also include the same adhesive as the window adhesive layer AL-W.

The window adhesive layer AL-W may be separated from the thin-film glass substrate UTG. Because the window protective layer PF has lower strength than the thin-film glass substrate UTG, a scratch may occur relatively easily. The window adhesive layer AL-W and the window protective layer PF may be separated from each other, and then a new window protective layer PF may be attached to the thin-film glass substrate UTG. A sum of respective thicknesses of the window adhesive layer AL-W and the window protective layer PF may be in a range of 100 micrometers to 110 micrometers (or about 100 micrometers to about 110 micrometers). For example, the sum of the respective thicknesses of the window adhesive layer AL-W and the window protective layer PF may be 105 micrometers (or about 105 micrometers).

The lower member LM may include a first adhesive layer AL1 which couples the display module DM and the window WM to each other. The first adhesive layer AL1 may be a pressure sensitive adhesive (PSA) film or an optically clear adhesive (OCA) member. For example, the first adhesive layer AL1 may include the pressure sensitive adhesive (PSA) film. In the display device DD according to some embodiments, the first adhesive layer AL1 may have a thickness in a range of 75 micrometers to 100 micrometers (or about 75 micrometers to about 100 micrometers).

The lower member LM may include a lower protective film PPL, a first support layer PLT, a cover layer SCV, a digitizer DTM, an electromagnetic shielding layer MML, a metal layer ML, a second support layer PP, and third to ninth adhesive layers AL3 to AL9. The third to ninth adhesive layers AL3 to AL9 may each include an adhesive such as pressure sensitive adhesive or optically clear adhesive. According to some embodiments of the present disclosure, some of the foregoing components may be omitted.

The lower protective film PPL may be located below the display module DM. The lower protective film PPL may protect a lower portion of the display module DM. The lower protective film PPL may include a flexible synthetic resin film. For example, the lower protective film PPL may include polyethylene terephthalate.

According to some embodiments of the present disclosure, the lower protective film PPL may not be located in a bending area BA. The lower protective film PPL may include a first lower protective film PPL-1 which protects a first area AA1 of the display panel DP (see FIG. 3), and a second lower protective film PPL-2 which protects a second area AA2 of the display panel (see FIG. 3).

The third adhesive layer AL3 couples the lower protective film PPL and the display panel DP to each other. The third adhesive layer AL3 may include a first portion AL3-1 corresponding to the first lower protective film PPL-1, and a second portion AL3-2 corresponding to the second lower protective film PPL-2.

A sum of respective thicknesses of the display module DM, the third adhesive layer AL3, and the lower protective film PPL may be in a range of 90 micrometers to 120 micrometers (or about 90 micrometers to about 120 micrometers). For example, the sum of the respective thicknesses of the display module DM, the third adhesive layer AL3, and the lower protective film PPL may be 105 micrometers (or about 105 micrometers).

The lower protective film PPL may be located below the base layer BL of the display panel DP described with reference to FIGS. 4 and 5. According to some embodiments, the third adhesive layer AL3 may be directly located below the base layer BL of the display panel DP, and the lower protective film PPL may be directly located below the third adhesive layer AL3.

When the bending area BA is bent, the second lower protective film PPL-2 together with the second area AA2 may be located below the first area AA1 and the first lower protective film PPL-1. As the lower protective film PPL is not located in the bending area BA, the bending area BA may be more easily bent. The second lower protective film PPL-2 may be attached to the second support layer PP through the ninth adhesive layer AL9. The ninth adhesive layer AL9 may be omitted.

The bending area BA has a curvature (e.g., a set or predetermined curvature) and a radius of curvature (e.g., a set or predetermined radius of curvature). The radius of curvature may be in a range of 0.1 millimeters (mm) to 0.5 mm (or about 0.1 mm to about 0.5 mm). The display device DD may further include a bending protective layer located in the bending area BA. The bending protective layer may overlap the bending area BA, the first area AA1, and the second area AA2. The bending protective layer may be located on a portion of the first area AA1 and a portion of the second area AA2. The bending protective layer may be bent together with the bending area BA. The bending protective layer protects the bending area BA from an external impact and controls a neutral plane of the bending area BA. The bending protective layer controls stress of the bending area BA such that the neutral plane is closer to signal lines located on the bending area BA.

The fourth adhesive layer AL4 couples the lower protective film PPL and the first support layer PLT to each other. The fourth adhesive layer AL4 used herein may be referred to as a first additional adhesive layer. The fourth adhesive layer AL4 may have a thickness in a range of 10 micrometers to 20 micrometers (or about 10 micrometers to about 20 micrometers). For example, the thickness of the fourth adhesive layer AL4 may be 16 micrometers (or about 16 micrometers).

The fourth adhesive layer AL4 may include a first portion AL4-1 and a second portion AL4-2 which are spaced apart from each other. A separation distance between the first portion AL4-1 and the second portion AL4-2 may be in a range of 7 mm to 15 mm (or about 7 mm to about 15 mm).

The first support layer PLT is located below the lower protective film PPL. The first support layer PLT supports components located above the support layer and maintains an unfolded state and a folded state of the display device DD. The first support layer PLT may have higher strength than the lower protective film PPL. The first support layer PLT at least includes a first support portion PLT-1 corresponding to a first non-folding area NFA10, and a second support portion PLT-2 corresponding to a second non-folding area NFA20. The first support portion PLT-1 and the second support portion PLT-2 are spaced apart from each other in the second direction DR2.

The first support layer PLT may include a folding portion PLT-F which corresponds to a folding area FA0 and is located between the first support portion PLT-1 and the second support portion PLT-2, and in which a plurality of opening portions OP are defined. The plurality of opening portions OP may be arranged such that the folding area FA0 has a lattice shape on a plane. The first support portion PLT-1, the second support portion PLT-2, and the folding portion PLT-F may have a one-body shape.

Upon the folding operations illustrated in FIGS. 1B and 1C, the folding portion PLT-F may prevent or reduce instances of contaminants or foreign matter entering from below a central area of the lower protective film PPL, which is opened from the first support portion PLT-1 and the second support portion PLT-2. Due to the plurality of opening portions OP, the flexibility of the folding portion PLT-F is relatively improved. In addition, the fourth adhesive layer AL4 may not be located on the folding portion PLT-F, and thus the flexibility of the first support layer PLT may be relatively improved. According to some embodiments of the present disclosure, the folding portion PLT-F may be omitted. In this case, the first support layer PLT includes the first support portion PLT-1 and the second support portion PLT-2 which are spaced apart from each other.

The first support layer PLT may be selected from materials which may transmit, without loss or with the minimum loss, an electromagnetic field generated from the digitizer DTM to be described later. The first support layer PLT may include a material having an insulating property. The first support layer PLT may include a non-metal material. The first support layer PLT may include a reinforced fiber composite material. The first support layer PLT may include a reinforced fiber located in an inner side of a matrix portion. The reinforced fiber may be a carbon fiber or a glass fiber. The matrix portion may include a polymer resin. The matrix portion may include a thermoplastic resin. For example, the matrix portion may include a polyamide-based resin or a polypropylene-based resin. For example, the reinforced fiber composite material may be carbon fiber reinforced plastic (CFRP) or glass fiber reinforced plastic (GFRP). The first support layer PLT may have a thickness in a range of 150 micrometers to 200 micrometers (or about 150 micrometers to about 200 micrometers).

The cover layer SCV and the digitizer DTM are located below the first support layer PLT. The cover layer SCV is arranged to overlap the folding area FA0. The digitizer DTM may include a first digitizer DTM-1 and a second digitizer DTM-2 which overlap the first support portion PLT-1 and the second support portion PLT-2, respectively. A portion of each of the first digitizer DTM-1 and the second digitizer DTM-2 may also be located below the cover layer SCV.

The fifth adhesive layer AL5 couples the first support layer PLT and the digitizer DTM to each other, and the eighth adhesive layer AL8 couples the cover layer SCV and the first support layer PLT to each other. The fifth adhesive layer AL5 may include a first portion AL5-1 which couples the first support portion PLT-1 to the first digitizer DTM-1, and a second portion AL5-2 which couples the second support portion PLT-2 to the second digitizer DTM-2.

The cover layer SCV may be located between the first portion AL5-1 and the second portion AL5-2 in the second direction DR2. The cover layer SCV may be spaced apart from the digitizer DTM in order to prevent or reduce interference with the digitizer DTM in the unfolded state. A sum of respective thicknesses of the cover layer SCV and the eighth adhesive layer AL8 may be less than a thickness of the fifth adhesive layer AL5. The sum of the respective thicknesses of the cover layer SCV and the eighth adhesive layer AL8 may be in a range of 10 micrometers to 20 micrometers (or about 10 micrometers to about 20 micrometers). For example, the sum of the respective thicknesses of the cover layer SCV and the eighth adhesive layer AL8 may be 16 micrometers (or about 16 micrometers). The thickness of the fifth adhesive layer AL5 may be in a range of 15 micrometers to 25 micrometers (or about 15 micrometers to about 25 micrometers). For example, the thickness of the fifth adhesive layer AL5 may be 20 micrometers (or about 20 micrometers).

The cover layer SCV may be manufactured in the form of a sheet and attached to the first support layer PLT. The cover layer SCV may be attached to a lower side of a portion corresponding to the folding portion PLT-F of the first support layer PLT. As the cover layer SCV is attached to the lower side of the folding portion PLT-F, the cover layer SCV may prevent or reduce instances of contaminants such as moisture, foreign matter, and the like entering the plurality of opening portions OP defined in the folding portion PLT-F. The cover layer SCV may include a material having a lower elastic modulus, for example, thermoplastic polyurethane. The cover layer SCV may be attached to the lower side of the folding portion PLT-F of the first support layer PLT but not located at a lower side of most of the first support portion PLT-1 and the second support portion PLT-2.

A width of the cover layer SCV in one direction may be greater than a width of the folding portion PLT-F in the one direction. According to some embodiments, on the basis of the second direction DR2 in which the first support portion PLT-1, the folding portion PLT-F, and the second support portion PLT-2 are arranged, the folding portion PLT-F may have a first width W1, and the cover layer SCV may have a second width W2. The first width W1 may have a smaller value than the second width W2. The first width W1 may have a smaller value than the second width W2 by 0.5 mm to 3 mm (or about 0.5 mm to about 3 mm). According to some embodiments, the first width W1 may be in a range of 6 mm to 10 mm (or about 6 mm to about 10 mm). For example, the first width W1 may be 8.65 mm (or about 8.65 mm). According to some embodiments, the second width W2 may be in a range of 9 mm to 15 mm (or about 9 mm to about 15 mm). For example, the second width W2 may be 10.65 mm (or about 10.65 mm).

The digitizer DTM is also referred to as an electromagnetic resonance (EMR) sensing panel and includes a plurality of loop coils which generate a magnetic field at a preset resonant frequency with an electronic pen. The magnetic field generated by the loop coils is applied to an LC resonance circuit including a capacitor and an inductor (coil) of the electronic pen. The coils generate a current by the received magnetic field, and transmits the generated current to the capacitor. Accordingly, the capacitor charges the current input from the coils and discharges the charged current to the coils. As a result, the magnetic field at the resonant frequency is emitted from the coils. The magnetic field emitted by the electronic pen may be reabsorbed by the loop coils of the digitizer, and accordingly, it may be determined which position in a touch screen the electronic pen is close to.

The digitizer DTM may include the first digitizer DTM-1 and the second digitizer DTM-2. The first digitizer DTM-1 and the second digitizer DTM-2 are arranged to be spaced from each other by a gap (e.g., a set or predetermined gap) GP. The gap GP may be in a range of 0.3 mm to 3 mm (or about 0.3 mm to about 3 mm), and may be arranged to correspond to the folding area FA0.

The digitizer DTM may have a thickness d3 in a range of 120 micrometers to 180 micrometers (or about 120 micrometers to about 180 micrometers). The thickness d3 of the digitizer DTM may be in a range of 140 micrometers to 160 micrometers (or about 140 micrometers to about 160 micrometers). The thickness d3 of the digitizer DTM may be, for example, 152 micrometers (or about 152 micrometers). As the thickness d3 of the digitizer DTM satisfies the foregoing range, the lower member LM including the digitizer DTM may protect against an external impact, and also, the display device DD excessively increasing in thickness may be prevented or reduced.

The electromagnetic shielding layer MML is located below the digitizer DTM. The electromagnetic shielding layer MML may be directly located below the digitizer DTM. The electromagnetic shielding layer MML may perform an electromagnetic shielding function. As the electromagnetic shielding layer MML performs the electromagnetic shielding function, the electromagnetic shielding layer MML may minimize an influence, on the digitizer DTM and the display panel DP, of electromagnetic waves generated from the electronic module EM (see FIG. 2A), the electro-optical module ELM (see FIG. 2A), the power module PSM (see FIG. 2A), and the like, which are located below the electromagnetic shielding layer MML. In addition, as the electromagnetic shielding layer MML is located, sensitivity of the digitizer DTM may be relatively improved, and signals applied to the digitizer DTM may be uniform, thereby relatively improving reliability of the display device DD.

The electromagnetic shielding layer MML may include magnetic metal powder (MMP). The electromagnetic shielding layer MML may include the magnetic metal powder to perform the electromagnetic shielding function. The magnetic metal powder included in the electromagnetic shielding layer MML may include a soft magnetic powder alloy.

The electromagnetic shielding layer MML may include a first electromagnetic shielding layer MML-1 and a second electromagnetic shielding layer MML-2. The first electromagnetic shielding layer MML-1 may be located below the first digitizer DTM-1, and the second electromagnetic shielding layer MML-2 may be located below the second digitizer DTM-2. The first electromagnetic shielding layer MML-1 may be directly located below the first digitizer DTM-1, and the second electromagnetic shielding layer MML-2 may be directly located below the second digitizer DTM-2. The electromagnetic shielding layer MML may have a thickness in a range of 30 micrometers to 60 micrometers (or about 30 micrometers to about 60 micrometers).

The metal layer ML is located below the electromagnetic shielding layer MML. The metal layer ML may include a first metal layer ML1 and a second metal layer ML2 which overlap the first support portion PLT-1 and the second support portion PLT-2, respectively. The metal layer ML may release, to the outside, heat generated upon driving the digitizer DTM. The metal layer ML transfers the heat to be generated in the digitizer DTM to a lower side. The metal layer ML may have high electrical conductivity and high thermal conductivity. The metal layer ML may include copper or aluminum. The metal layer ML having high electrical conductivity may prevent or reduce instances of the electromagnetic waves, which are generated from the electronic module EM (see FIG. 2A), the electro-optical module ELM (see FIG. 2A), the power module PSM (see FIG. 2A), and the like, located below the metal layer ML, being affected on the digitizer DTM as noise. The lower member LM according to some embodiments may include the electromagnetic shielding layer MML and the metal layer ML, which are located below the digitizer DTM, thereby preventing or reducing instances or degrees of performance of the digitizer DTM being decreased due to electronic components such as electronic modules included in the electronic apparatus.

The sixth adhesive layer AL6 couples the electromagnetic shielding layer MML and the metal layer ML to each other. The sixth adhesive layer AL6 may include a first portion AL6-1 and a second portion AL6-2 which correspond to the first metal layer ML1 and the second metal layer ML2, respectively. A sum of respective thicknesses of the metal layer ML and the sixth adhesive layer AL6 may be in a range of 15 micrometers to 25 micrometers (or about 15 micrometers to about 25 micrometers).

The second support layer PP is located below the metal layer ML. The second support layer PP may include a (2-1)-th support layer PP1 and a (2-2)-th support layer PP2 which overlap to the first metal layer ML1 and the second metal layer ML2, respectively. The second support layer PP may absorb an external impact applied from below. The second support layer PP may include an insulating material. According to some embodiments, the second support layer PP may include, for example, a polymer film. The second support layer PP may include polyimide, polycarbonate, polyamide, triacetylcellulose, polymethylmethacrylate, or polyethylene terephthalate. For example, the second support layer PP may include polyethylene terephthalate.

The seventh adhesive layer AL7 couples the metal layer ML and the second support layer PP to each other. The seventh adhesive layer AL7 may include a first portion AL7-1 and a second portion AL7-2 which correspond to the (2-1)-th support layer PP1 and the (2-2)-th support layer PP2, respectively. A sum of respective thicknesses of the second support layer PP and the seventh adhesive layer AL7 may be in a range of 1 micrometer to 10 micrometers (or about 1 micrometer to about 10 micrometers).

A magnetic field shielding sheet MSM is located below the second support layer PP. The magnetic field shielding sheet MSM shields a magnetic field generated from an electronic component located therebelow. The magnetic field shielding sheet MSM may prevent or reduce instances of the magnetic field generated from the electronic component interfering with the digitizer DTM. The electronic component may include the electronic module EM, the electro-optical module ELM, and the power module PSM, which are described above with reference to FIGS. 2A and 2B.

The magnetic field shielding sheet MSM includes a plurality of portions. At least a portion of the plurality of portions may have a different thickness. The plurality of portions may be arranged to conform to a step portion of a bracket located below the display device DD. The magnetic field shielding sheet MSM may have a structure in which a magnetic field shielding layer and an adhesive layer are alternately stacked. A portion of the magnetic field shielding sheet MSM may be directly attached to a lower side of the second support layer PP, and a portion of the magnetic field shielding sheet MSM may be directly attached to a lower side of the electromagnetic shielding layer MML.

A through-hole LTH may be defined in some members of the lower member LM. The through-hole LTH is arranged to overlap the sensing area DP-TA in FIG. 2A. As illustrated in FIG. 6, the through-hole LTH may penetrate from the fifth adhesive layer AL5 to the second support layer PP. The through-hole LTH has a similar structure to a path of the optical signal from which a light blocking structure is removed, and the through-hole LTH may relatively improve the optical signal reception efficiency of the electro-optical module ELM.

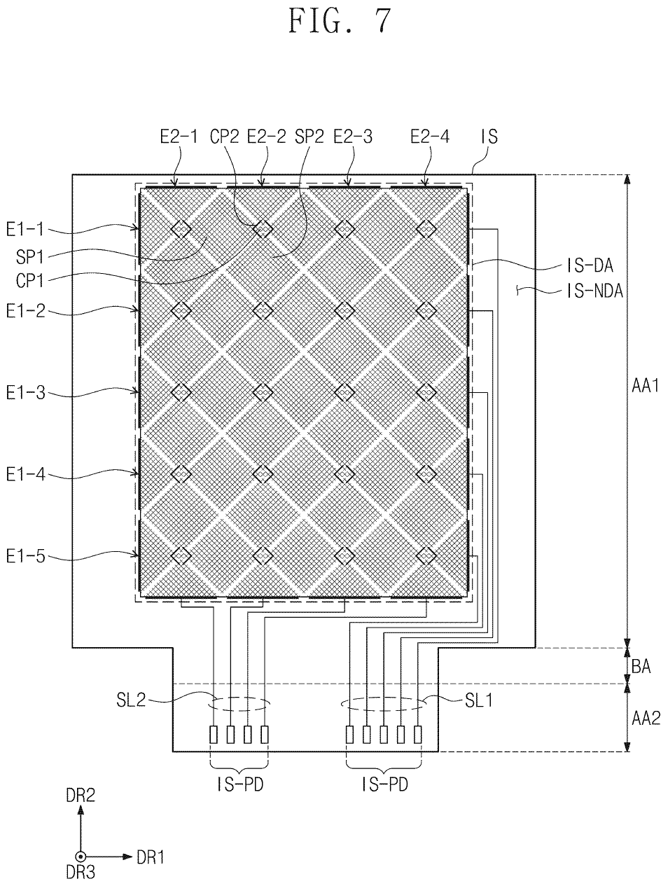

FIG. 7 is a plan view of an input sensor according to some embodiments of the present disclosure.

Referring to FIGS. 4, 5, and 7 together, an input sensor IS includes a sensing area IS-DA and a non-sensing area IS-NDA adjacent to the sensing area IS-DA. The sensing area IS-DA and the non-sensing area NSA may, respectively, correspond to the display area DP-DA and the non-display area DP-NDA of the display panel DP illustrated in FIG. 3. In addition, the input sensor IS may include areas the same as/similar to the first area AA1, the second area AA2, and the bending area BA which are included in the display panel DP.

The input sensor IS includes a plurality of sensing electrodes located in the sensing area IS-DA. The sensing electrodes may include first sensing electrodes E1-1 to E1-5 (hereinafter referred to as first electrodes) and second sensing electrodes E2-1 to E2-4 (hereinafter referred to as second electrodes), which are insulated and intersect with each other. The input sensor IS is located in the non-sensing area IS-NDA, and includes first signal lines SL1 electrically connected to the first electrodes E1-1 to E1-5, and second signal lines SL2 electrically connected to the second electrodes E2-1 to E2-4. The first electrodes E1-1 to E1-5, the second electrodes E2-1 to E2-4, the first signal lines SL1, and the second signal lines SL2 may be defined by a combination of the first sensor conductive layer 220 and the second sensor conductive layer 240 which are described above.

The first electrodes E1-1 to E1-5 and the second electrodes E2-1 to E2-4 may each include a plurality of conductive lines that intersect with each other. The plurality of conductive lines define a plurality of opening portions, and each of the first electrodes E1-1 to E1-5 and the second electrodes E2-1 to E2-4 may have a mesh shape. Each of the plurality of opening portions may be defined to correspond to the opening PDL-OP of the pixel defining film PDL illustrated in FIG. 5.

Any one of the first electrodes E1-1 to E1-5 and the second electrodes E2-1 to E2-4 may have a one-body shape. According to some embodiments, the first electrodes E1-1 to E1-5 having a one-body shape are provided as an example. The first electrodes E1-1 to E1-5 may include sensing patterns SP1 and connection patterns CP1. A portion of the second sensor conductive layer 240 described above may correspond to the first electrodes E1-1 to E1-5.

The second electrodes E2-1 to E2-4 may each include sensing patterns SP2 and bridge patterns CP2 (or connection patterns). Two adjacent sensing patterns SP2 of the sensing patterns SP2 may be connected to the bridge patterns CP2 through a contact hole passing through the intermediate sensor insulating layer 230 (see FIG. 5). A portion of the second sensor conductive layer 240 described above may correspond to the sensing patterns SP2. A portion of the first sensor conductive layer 220 described above may correspond to the bridge patterns CP2.

According to some embodiments, the bridge patterns CP2 are described as being formed from the first sensor conductive layer 220 illustrated in FIG. 5, and the first sensing electrodes E1-1 to E1-5 and the sensing patterns SP2 are described as being formed from the second sensor conductive layer 240 illustrated in FIG. 5. However, embodiments of the present disclosure are not limited thereto. For example, the first sensing electrodes E1-1 to E1-5 and the sensing patterns SP2 may be formed from the first sensor conductive layer 220 illustrated in FIG. 5, and the bridge patterns CP2 may be formed from the second sensor conductive layer 240 illustrated in FIG. 5.

One of the first signal lines SL1 and the second signal lines SL2 receives a transmission signal for sensing an external input from an external circuit, and the other thereof transmits, to the external circuit, a change in capacitance between the first electrodes E1-1 to E1-5 and the second electrodes E2-1 to E2-4 as a reception signal.

A portion of the second sensor conductive layer 240 described above may correspond to the first signal lines SL1 and the second signal lines SL2. The first signal lines SL1 and the second signal lines SL2 may have a multilayer structure, and may include a first layer line formed from the first sensor conductive layer 220 described above and a second layer line formed from the second sensor conductive layer 240 described above. The first layer line and the second layer line may be connected to each other through the contact hole passing through the intermediate sensor insulating layer 230.

FIG. 8A is a cross-sectional view of an input sensor according to some embodiments of the present disclosure. FIG. 8A simply illustrates arrangement and connection relationships between a sensor insulating layer and a sensor conductive layer, which are included in the input sensor, when viewed on a cross-section.

Referring to FIG. 8A, an input sensor IS may include a first sensor insulating layer 210, a first sensor conductive layer 220, an intermediate sensor insulating layer 230, a second sensor conductive layer 240, a second sensor insulating layer 250, and a protective layer 260.

The first sensor insulating layer 210 may be directly located on an encapsulation layer TFE of the display panel DP (see FIG. 5). The first sensor insulating layer 210 may be an inorganic layer including at least one of silicon nitride, silicon oxynitride, or silicon oxide. Alternatively, the first sensor insulating layer 210 may be an organic layer including epoxy resin, acryl-based resin, or imide-based resin. The first sensor insulating layer 210 may have a single-layer structure, or have a multilayer structure in which layers are stacked in the third direction DR3.

The first sensor conductive layer 220 is located on the first sensor insulating layer 210. The first sensor conductive layer 220 may be directly located on the first sensor insulating layer 210. The first sensor conductive layer 220 may include first sensor conductive patterns CDP1. FIG. 8A illustrates only one first sensor conductive pattern CDP1, but the first sensor conductive pattern CDP1 may be provided in plurality. The plurality of first sensor conductive patterns CDP1 may be each located on the first sensor insulating layer 210, and be arranged to be spaced apart from each other in one direction.

The first sensor conductive layer 220 may include a first lower conductive layer CL10, a second lower conductive layer CL20, which is located above the first lower conductive layer CL10 and in contact with first lower conductive layer CL10, a third lower conductive layer CL30 which is located below the first lower conductive layer CL10 and in contact with the first lower conductive layer CL10. According to some embodiments of the present disclosure, the third lower conductive layer CL30 may be omitted. The first lower conductive layer CL10 may have a first reflectance, a first conductivity, and a first thickness. The second lower conductive layer CL20 may have a second reflectance lower than the first reflectance, a second conductivity lower than the first conductivity, and a second thickness smaller than first thickness. The first lower conductive layer CL10 having lower resistance corresponds to a substantial signal transfer path. In the input sensor IS according to some embodiments, the thickness may be increased through a three-layer structure so that a plurality of conductive patterns are located within a small surface area on a plane. The second lower conductive layer CL20 having the lower reflectance may cover the first lower conductive layer CL10 and reduce the reflectance of external light. However, unlike the illustrated embodiments, the first sensor conductive layer 220 may have a single-layer structure, not the three-layer structure. The first sensor conductive layer 220 may have a single-layer structure made of a single material.

The intermediate sensor insulating layer 230 may be located on the first sensor conductive layer 220. The intermediate sensor insulating layer 230 may cover top and side surfaces of the plurality of first sensor conductive patterns CDP1. The intermediate sensor insulating layer 230 may include an inorganic film. The inorganic film may include at least one of aluminum oxide, titanium oxide, silicon oxide, silicon nitride, silicon oxynitride, zirconium oxide, or hafnium oxide. Alternatively, the intermediate sensor insulating layer 230 may include an organic film. The organic film may include at least one of acryl-based resin, methacryl-based resin, polyisoprene, vinyl-based resin, epoxy-based resin, urethane-based resin, cellulose-based resin, siloxane-based resin, polyimide-based resin, polyamide-based resin, or perylene-based resin. Alternatively, the organic film may include a melamine resin.

The second sensor conductive layer 240 is located on the intermediate sensor insulating layer 230. The second sensor conductive layer 240 may be directly located on the intermediate sensor insulating layer 230. The second sensor conductive layer 240 may include a plurality of second sensor conductive patterns CDP2. The plurality of second sensor conductive patterns CDP2 may be each located on the intermediate sensor insulating layer 230, and be arranged to be spaced apart from each other along the one direction.

The second sensor conductive layer 240 may include a first upper conductive layer CL1, a second upper conductive layer CL2, which is located above the first upper conductive layer CL1 and in contact with first upper conductive layer CL1, a third upper conductive layer CL3 which is located below the first upper conductive layer CL1 and in contact with the first upper conductive layer CL1. The first upper conductive layer CL1 of the second sensor conductive layer 240 may include the same material and have the same thickness as the first lower conductive layer CL10 of the first sensor conductive layer 220. The second upper conductive layer CL2 of the second sensor conductive layer 240 may include the same material and have the same thickness as the second lower conductive layer CL20 of the first sensor conductive layer 220. The third upper conductive layer CL3 of the second sensor conductive layer 240 may include the same material and have the same thickness as the third lower conductive layer CL30 of the first sensor conductive layer 220. However, unlike the illustrated embodiments, the second sensor conductive layer 240 may have a single-layer structure, not the three-layer structure. The second sensor conductive layer 240 may have a single-layer structure made of a single material.

A portion of the second sensor conductive layer 240 may be electrically connected to the first sensor conductive layer 220 through a contact hole CNT passing through the intermediate sensor insulating layer 230. A portion of the plurality of second sensor conductive patterns CDP2 may be electrically connected to a portion of the first sensor conductive patterns CDP1 through the contact hole CNT.

The second sensor insulating layer 250 is located on the second sensor conductive layer 240. The second sensor insulating layer 250 may include an organic material, and be provided to have a thickness (e.g., a set or predetermined thickness) or greater and planarize upper portions of the conductive patterns of the conductive layer located below the second sensor insulating layer 250. The second sensor insulating layer 250 may have a larger thickness than each of the first sensor insulating layer 210, the first sensor conductive layer 220, the intermediate sensor insulating layer 230, the second sensor conductive layer 240, which are located below the second sensor insulating layer 250. A top surface of the second sensor insulating layer 250 may be a flat surface.

The second sensor insulating layer 250 includes a low-temperature curable organic material. The second sensor insulating layer 250 may include an organic material curable at a low temperature of 100° C. (or about 100° C.) or less. The second sensor insulating layer 250 may include, for example, a melamine resin. The second sensor insulating layer 250 may include Hexamethyol melamine.

A second thickness d2 that is a total thickness of the second sensor insulating layer 250 may be greater than a first thickness d1 that is a thickness of the first sensor conductive pattern CDP1, and for example, the second thickness d2 may be in a range of 2.5 times to 4.5 times (or about 2.5 times to about 4.5 times) the first thickness d1. According to some embodiments, the first thickness d1 may be in a range of 3000 Å to 4000 Å (or about 3000 Å to about 4000 Å). For example, the first thickness d1 may be 3300 Å (or about 3300 Å). According to some embodiments, the second thickness d2 may be in a range of 10000 Å to 13000 Å (or about 10000 Å to about 13000 Å). For example, the second thickness d2 may be 11950 Å (or about 11950 Å). The second thickness d2 may correspond to a minimum distance from a top surface of the intermediate sensor insulating layer 230, on which the second sensor conductive patterns CDP2 are not located, to a top surface of the second sensor insulating layer 250.

A third thickness d3 that is a thickness of the second sensor insulating layer 250 located on the first sensor conductive pattern CDP1 may be greater than the first thickness d1 that is the thickness of the first sensor conductive pattern CDP1, and for example, the third thickness d3 may be in a range of 1.4 times to 3.0 (or about 1.4 times to about 3.0) times the first thickness d1. According to some embodiments, the third thickness d3 may be in a range of 6000 Å to 7000 Å (or about 6000 Å to about 7000 Å). For example, the third thickness d3 may be 6400 Å (or about 6400 Å). The third thickness d3 may correspond to a minimum distance from the top surface of the second sensor insulating layer 250 to a top surface of the first sensor conductive pattern CDP1.

The protective layer 260 is located on the second sensor insulating layer 250. The protective layer 260 may be formed through deposition, and be an inorganic film having a smaller thickness than the second sensor insulating layer 250. The protective layer 260 may include, for example, at least one of aluminum oxide, titanium oxide, silicon oxide, silicon nitride, silicon oxynitride, zirconium oxide, or hafnium oxide. Alternatively, the protective layer 260 may include a transparent conductive oxide (TCO). The protective layer 260 may include an inorganic material, protect the conductive patterns located therebelow from an external impact, and block moisture and oxygen. In addition, the protective layer 260 may protect, from a subsequent process, the organic material of the second sensor insulating layer 250 located below the protective layer 260. The organic material included in the second sensor insulating layer 250 has poor chemical resistance, but the protective layer 260 including an inorganic material may entirely cover the top surface of the second sensor insulating layer 250 so that damage to the second sensor insulating layer 250 due to a material added in the subsequent process may be prevented or reduced.

The input sensor IS included in the display device according to some embodiments may be located on the sensor conductive layers 220 and 240 and include the second sensor insulating layer 250 including an organic material, thereby relatively improving durability and pressing impact resistance characteristics of the input sensor IS and the display device.

The display device according to some embodiments may include a component for performing a folding operation, and when the folding area FA described above with reference to FIGS. 1A to 1C is pressed, the folding area FA has poorer pressing impact resistance characteristics than non-folding areas NFA1 and NFA2. For example, when the folding area FA is pressed, a counter-curvature portion is generated in a stepped portion between the first support layer PLT and the digitizer DTM described above with reference to FIG. 7, and tensile stress applied due to this may propagate to the input sensor IS above the display panel DP.

Unlike the display device according to some embodiments, in a case in which the second sensor insulating layer 250 including an organic material is not located on the sensor conductive layers 220 and 240 and an inorganic layer or the like for protecting the conductive layers is directly located on the sensor conductive layers 220 and 240, the propagated tensile stress may be concentrated on the inorganic layer, and thus a crack may be initiated. In particular, an inorganic layer having a small thickness may not cover the step portion due to the sensor conductive layers 220 and 240, and thus a crack may be initiated in the inorganic layer in an area corresponding to the stepped portion of the sensor conductive layers 220 and 240. The crack initiated in the inorganic layer may propagate to the encapsulation layer TFE located at the lower portion, and a progressive dark spot may be generated. As a result, display characteristics of the display device may be decreased.

In the display device according to some embodiments, as the second sensor insulating layer 250 including an organic material is located on the sensor conductive layers 220 and 240, the tensile stress, which is propagated as the folding area FA is pressed, may be effectively mitigated. In particular, the second sensor insulating layer 250 including an organic material may have a large thickness to cover the stepped portion due to the sensor conductive layers 220 and 240, and thus a portion on which the tensile stress is concentrated may be removed to prevent or reduce instances of the initiation of the crack. Thus, the input sensor according to some embodiments and the display device including the same may be relatively improved in durability and pressing impact resistance characteristics.

FIGS. 8B to 8D are each a cross-sectional view of an input sensor according to some embodiments of the present disclosure. FIGS. 8B to 8D each simply illustrate arrangement and connection relationships between a sensor insulating layer and a sensor conductive layer, which are included in the input sensor according to some embodiments, when viewed on a cross-section corresponding to FIG. 8A.

Referring to FIG. 8B, unlike the embodiments in FIG. 8A, an intermediate sensor insulating layer 230-1 in an input sensor IS-1 may include a low-temperature curable organic material. The intermediate sensor insulating layer 230-1 may include the same material as a material included in a second sensor insulating layer 250. The intermediate sensor insulating layer 230-1 may include a melamine resin. The intermediate sensor insulating layer 230-1 may include Hexamethyol melamine.

A fifth thickness d5 that is a total thickness of the intermediate sensor insulating layer 230-1 may be greater than a fourth thickness d4 that is a thickness of a first sensor conductive pattern CDP1, and for example, the fifth thickness d5 may be 2.5 times to 4.5 times (or about 2.5 times to about 4.5 times) the fourth thickness d4. According to some embodiments, the fourth thickness d4 may be in a range of 3000 Å to 4000 Å (or about 3000 Å to about 4000 Å). For example, the fourth thickness d4 may be 3300 Å (or about 3300 Å). According to some embodiments, the fifth thickness d5 may be in a range of 10000 Å to 13000 Å (or about 10000 Å to about 13000 Å). For example, the fifth thickness d5 may be 11950 Å (or about 11950 Å). The fifth thickness d5 may correspond to a minimum distance from a top surface of the first sensor insulating layer 210, on which the first sensor conductive pattern CDP1 is not located, to a top surface of the intermediate sensor insulating layer 230-1.

Referring to FIGS. 8C and 8D, unlike the embodiments in FIG. 8A, sensor conductive layers 220′ and 240′ in input sensors IS-2 and IS-3 may be each provided as a single layer. That is, unlike the input sensor IS in FIG. 8A in which the sensor conductive layers 220 and 240 include a plurality of conductive layers located on different insulating layers, in the input sensors IS-2 and IS-3 in FIGS. 8C and 8D, each of the sensor conductive layers 220′ and 240′ is provided as a single layer located on one insulating layer. In the input sensors IS-2 and IS-3 according to some embodiments, the sensor conductive layers 220′ and 240′ may include only one conductive layer located on the one insulating layer.

As in FIG. 8C, the sensor conductive layer 220′ including a plurality of sensor conductive patterns CDP1′ may be located on a first sensor insulating layer 210, and a cover sensor insulating layer 230-2 including a low-temperature curable organic material may be located on the sensor conductive layer 220′. The cover sensor insulating layer 230-2 may cover top and side surfaces of the sensor conductive layer 220′. In the input sensor IS-2, a third sensor insulating layer 260 may be directly located on the cover sensor insulating layer 230-2.

As in FIG. 8D, the sensor conductive layer 240′ including a plurality of sensor conductive patterns CDP2′ may be located on an intermediate sensor insulating layer 230, and a second sensor conductive layer 240 including a low-temperature curable organic material may be located on the sensor conductive layer 240′. The second sensor conductive layer 240 may cover top and side surfaces of the sensor conductive layer 240′. Unlike the embodiments illustrated in FIG. 8A, a separate sensor conductive layer may not be located on the first sensor insulating layer 210.

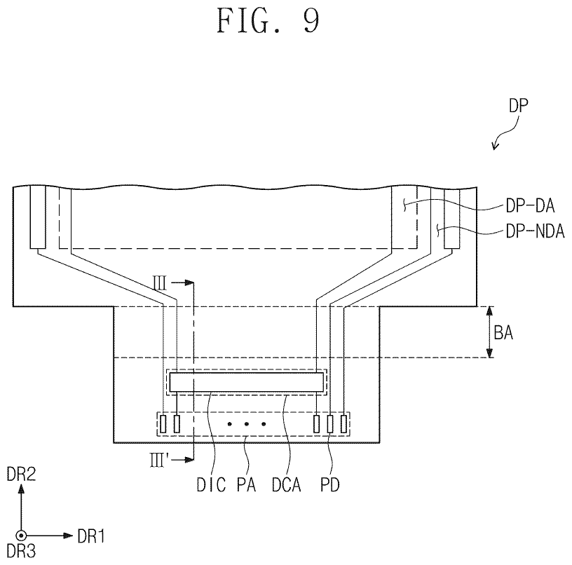

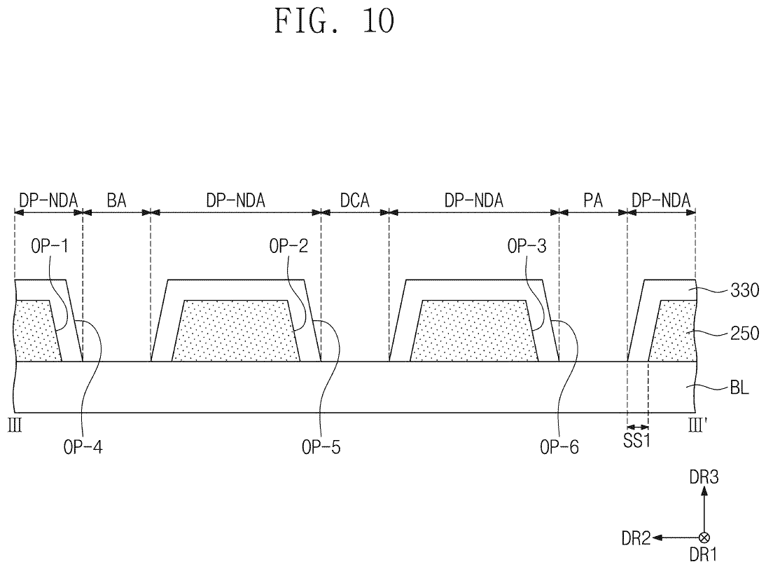

FIG. 9 is a plan view of a portion of a display panel according to some embodiments of the present disclosure. FIG. 10 is a cross-sectional view of some components of a display device according to some embodiments of the present disclosure. In a cross-section corresponding to line III-III′ illustrated in FIG. 9, FIG. 10 simply illustrates a partial cross-section of a second sensor insulating layer 250 included in an input sensor, and a planarization layer 330 included in an anti-reflective layer of the display device.

Referring to FIGS. 9 and 10, an area in which a driving chip DIC is located in a non-display area DP-NDA of a display panel DP may be referred to as a chip area DCA. An area in which a plurality of pads PD are located in the non-display area DP-NDA may be referred to as a pad area PA. In addition, the display panel DP includes a bending area BA located between a display area DP-DA and the pad area PA. The bending area BA may be an area which is bent with a curvature (e.g., a set or predetermined curvature) and a radius of curvature (e.g., a set or predetermined radius of curvature).

A second sensor insulating layer 250 included in the input sensor IS (see FIG. 6), and a planarization layer 330 included in the anti-reflective layer ARL (see FIG. 6) may include the same material. Each of the second sensor insulating layer 250 and the planarization layer 330 may include a low-temperature curable organic material having excellent planarization characteristics. For example, each of the second sensor insulating layer 250 and the planarization layer 330 may include a melamine resin.

In the bending area BA, the chip area DCA, and the pad area PA of the non-display area DP-NDA, a portion of the second sensor insulating layer 250 of the input sensor IS (see FIG. 6) may be removed. The second sensor insulating layer 250 may not overlap each of the bending area BA, the chip area DCA, and the pad area PA. The second sensor insulating layer 250 may include an opening portion corresponding to each of the bending area BA, the chip area DCA, and the pad area PA. The second sensor insulating layer 250 may include a first opening portion OP-1 corresponding to the bending area BA, a second opening portion OP-2 corresponding to the chip area DCA, and a third opening portion OP-3 corresponding to the pad area PA.

In the bending area BA, the chip area DCA, and the pad area PA of the non-display area DP-NDA, a portion of the planarization layer 330 of the anti-reflective layer ARL (see FIG. 6) may be removed. The planarization layer 330 may not overlap each of the bending area BA, the chip area DCA, and the pad area PA. The planarization layer 330 may include an opening portion corresponding to each of the bending area BA, the chip area DCA, and the pad area PA. The planarization layer 330 may include a fourth opening portion OP-4 corresponding to the bending area BA, a fifth opening portion OP-5 corresponding to the chip area DCA, and a sixth opening portion OP-6 corresponding to the pad area PA.

A width of the opening portion defined in the second sensor insulating layer 250 may be greater than a width of the opening portion defined in the planarization layer 330. The opening portion defined in the second sensor insulating layer 250 and the opening portion defined in the planarization layer 330 may be spaced from each other by a first gap ss1 in one direction. The first gap SS1 may be in a range of 1 micrometer to 3 micrometers (or about 1 micrometer to about 3 micrometers). For example, the first gap SS1 may be 2 micrometers (or about 2 micrometers). The first opening portion OP-1 may be spaced from the fourth opening portion OP-4 by the first gap SS1, the second opening portion OP-2 may be spaced from the fifth opening portion OP-5 by the first gap SS1, and the third opening portion OP-3 may be spaced from the sixth opening portion OP-6 by the first gap SS1.

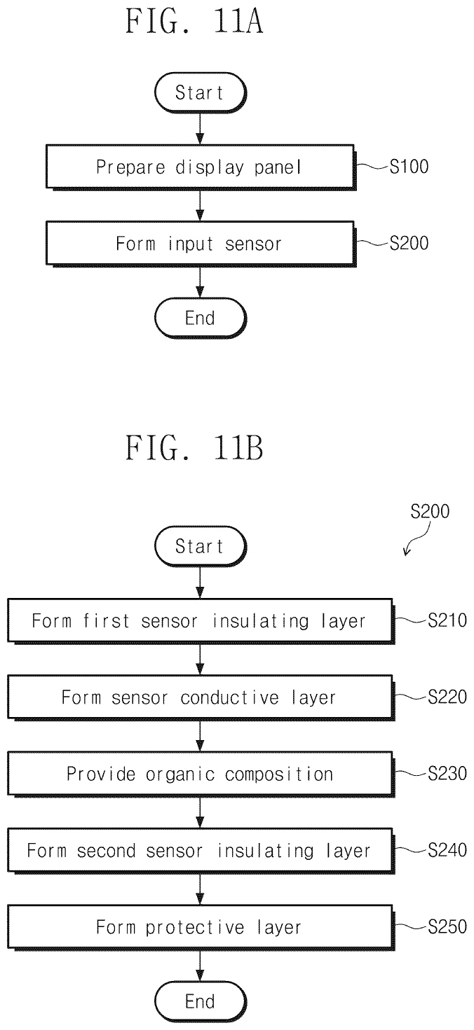

FIG. 11A is a flowchart of a method for manufacturing a display device according to some embodiments of the present disclosure. Although FIG. 11A illustrates various operations in a method for manufacturing a display device, embodiments according to the present disclosure are not limited thereto, and according to some embodiments, the method may include additional operations, or fewer operations, or the order of operations may vary, unless otherwise stated or implied, without departing from the spirit and scope of embodiments according to the present disclosure.

FIG. 11B is a flowchart of some steps of the method for manufacturing the display device according to some embodiments of the present disclosure.

FIG. 11B illustrates operations included in forming an input sensor (S200) in sequence. Although FIG. 11B illustrates various operations in an operation for forming an input sensor, embodiments according to the present disclosure are not limited thereto, and according to some embodiments, the operation may include additional operations, or fewer operations, or the order of operations may vary, unless otherwise stated or implied, without departing from the spirit and scope of embodiments according to the present disclosure.

Referring to FIG. 11B, the method for manufacturing the display device according to some embodiments of the present disclosure includes preparing a display panel including a plurality of pixels (S100) and the forming of the input sensor located on the display panel (S200). Referring to FIG. 11B, the forming of the input sensor (S200) includes forming a first sensor insulating layer on the display panel (S210), forming, on the first sensor insulating layer, a sensor conductive layer including a plurality of conductive patterns (S220), providing an organic composition so as to cover each of the plurality of conductive patterns (S230), curing the organic composition to form a second sensor insulating layer (S240), and depositing an inorganic material onto the second sensor insulating layer to form a protective layer (S250).

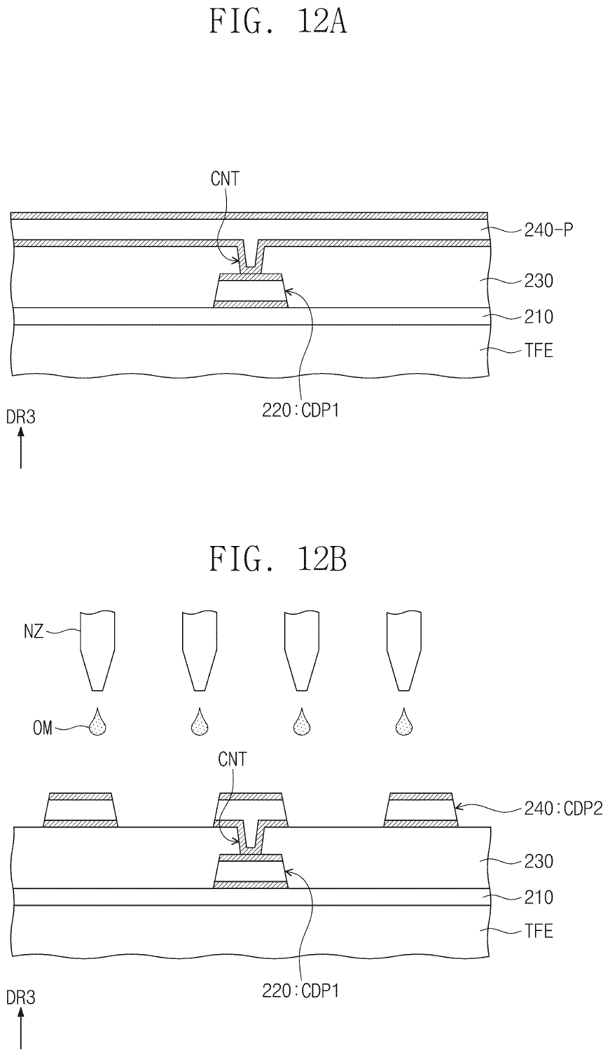

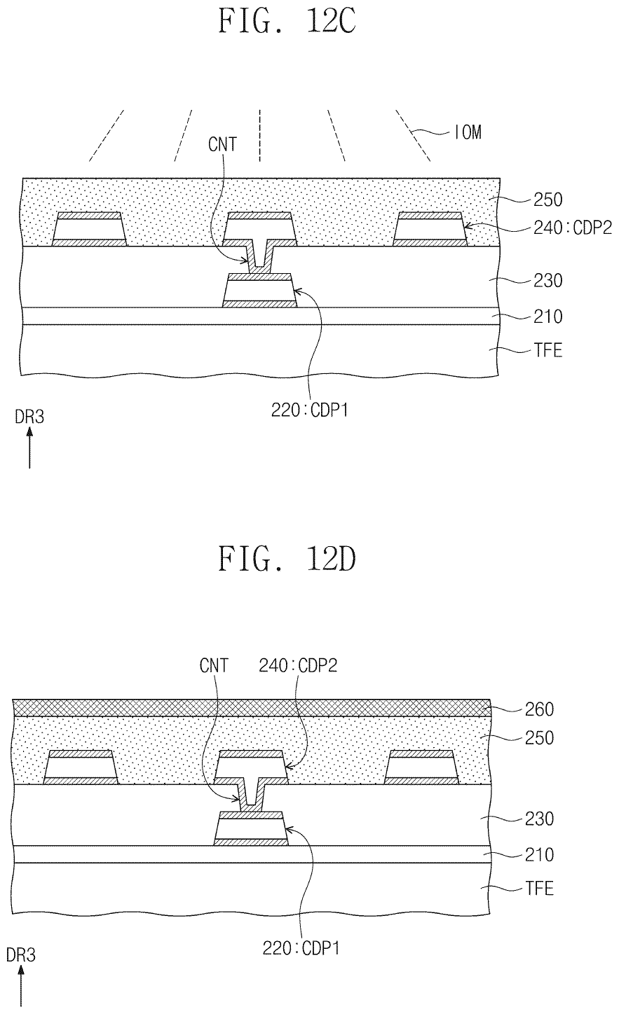

FIGS. 12A to 12D are cross-sectional views of some steps of a method for manufacturing a display device according to some embodiments of the present disclosure. In a cross-section corresponding to FIG. 8, FIGS. 12A to 12D illustrate, in sequence, states in forming an input sensor in the method for manufacturing the display device.

Referring to FIGS. 11B, 12A, and 12B together, the forming of the input sensor (S200) includes forming a first sensor insulating layer 210 (S210), and forming, on the first sensor insulating layer 210, sensor conductive layers 220 and 240 including a plurality of conductive patterns (S220). An inorganic material may be deposited to form the first sensor insulating layer 210.

The sensor conductive layers 220 and 240 may include a first sensor conductive layer 220 and a second sensor conductive layer 240. When forming the sensor conductive layers 220 and 240, a conductive layer in the form of a common layer may be formed and then patterned to form the sensor conductive layers 220 and 240 including the plurality of conductive patterns. According to some embodiments, a conductive layer in the form of a common layer may be formed on the first sensor insulating layer 210 and then patterned so that the first sensor conductive layer 220 is formed so as to include first sensor conductive patterns CDP1.

After the first sensor conductive layer 220 including the first sensor conductive patterns CDP1 are formed, an intermediate sensor insulating layer 230 which covers the first sensor conductive layer 220 may be formed, and a contact hole CNT which exposes a top surface of at least one of the first sensor conductive patterns CDP1 may be formed in the intermediate sensor insulating layer 230.

According to some embodiments, a preliminary conductive layer 240-P in the form of a common layer may be formed on the intermediate sensor insulating layer 230, and then the preliminary conductive layer 240-P may be patterned to form the second sensor conductive layer 240 including a plurality of second sensor conductive patterns CDP2. The preliminary conductive layer 240-P may have a three-layer structure of titanium/aluminum/titanium. According to some embodiments, the patterning of the preliminary conductive layer 240-P may be performed through a dry etching process after a photoresist mask is formed.

Referring to FIGS. 11B, 12B, and 12C together, the forming of the input sensor (S200) includes providing an organic composition OM so as to cover each of the conductive patterns (S230), and curing the organic composition OM to form a second sensor insulating layer 250 (S240). The organic composition OM may be provided on the second sensor conductive patterns CDP2 through at least one nozzle NZ. The organic composition OM may be provided on the entirety of the intermediate sensor insulating layer 230 and the second sensor conductive patterns CDP2.

The organic composition OM includes a low-temperature curable organic material. The organic composition OM may include an organic material curable at a low temperature of 100° C. (or about 100° C.) or less. The organic composition OM may include, for example, a melamine resin. The organic composition OM may include Hexamethyol melamine. The organic composition OM may be cured at a low temperature of 100° C. (or about 100° C.) or less to form the second sensor insulating layer 250. The organic composition OM may be, for example, photo-cured.

Only a portion of the organic composition OM may be cured, and the remaining portion which is not cured may be removed so that the second sensor insulating layer 250 having an opening portion in the portion is formed. As described above with reference to FIGS. 9 and 10, the organic composition OM provided to correspond to a bending area BA, a chip area DCA, and a pad area PA may not be cured, and thus an opening portion corresponding to each of the bending area BA, the chip area DCA, and the pad area PA may be formed in the second sensor insulating layer 250.

Referring to FIGS. 11B, 12C, and 12D together, the forming of the input sensor (S200) includes depositing an inorganic material IOM onto the second sensor insulating layer 250 to form a protective layer 260 (S250).

The inorganic material IOM may be provided on the second sensor insulating layer 250 to form the protective layer 260. The protective layer 260 may be formed by providing the inorganic material IOM to a top surface of the second sensor insulating layer 250 through deposition. The protective layer 260 may be formed through chemical vapor deposition (CVD). The inorganic material IOM may include, for example, at least one of aluminum oxide, titanium oxide, silicon oxide, silicon nitride, silicon oxynitride, zirconium oxide, or hafnium oxide. Alternatively, the inorganic material IOM may include a transparent conductive oxide (TCO).

According to some embodiments, the anti-reflective layer ARL (see FIG. 6) may be formed on the protective layer 260 after the protective layer 260 is formed. The protective layer 260 may protect the second sensor insulating layer 250 having poor chemical resistance from materials added when forming the anti-reflective layer ARL (see FIG. 6). The planarization layer 330 (see FIG. 6) included in the anti-reflective layer ARL (see FIG. 6) may be formed using the same material as the organic composition OM which forms the second sensor insulating layer 250, and like the second sensor insulating layer 250, the planarization layer 330 may be formed such that an opening portion corresponding to each of the bending area BA, the chip area DCA, and the pad area PA is provided.

According to some embodiments of the present disclosure, the phenomenon, in which due to the pressure applied to the portion to be folded in the display device, the crack is initiated in the display panel and the input sensor, and the crack propagates to generate the progressive dark spot, may be prevented or reduced. Thus, the durability and pressing impact resistance characteristics of the display device may be relatively improved.

Although aspects of some embodiments of the present invention have been described, it is understood that the present invention should not be limited to these embodiments but various changes and modifications can be made by one ordinary skilled in the art within the spirit and scope of the present invention as hereinafter claimed. Therefore, the technical scope of embodiments according to the present disclosure is not limited to the contents described in the detailed description of the specification, but should be determined by the appended claims, and their equivalents.

What is claimed is:

1. A display device comprising:
a display panel comprising a plurality of pixels; and
an input sensor on the display panel,
wherein the input sensor comprises:
a first sensor insulating layer on the display panel;
a sensor conductive layer on the first sensor insulating layer and comprising a plurality of conductive patterns;
a second sensor insulating layer configured to cover each of the plurality of conductive patterns and comprising an organic material; and
a protective layer on the second sensor insulating layer and comprising an inorganic material.

2. The display device of claim 1, wherein the input sensor further comprises an intermediate sensor insulating layer configured to cover at least a portion of the sensor conductive layer.

3. The display device of claim 2, wherein the sensor conductive layer comprises:
a first sensor conductive layer on the first sensor insulating layer and comprising a plurality of first sensor conductive patterns; and
a second sensor conductive layer on the intermediate sensor insulating layer and comprising a plurality of second sensor conductive patterns.

4. The display device of claim 3, wherein the protective layer covers each of the plurality of second sensor conductive patterns.

5. The display device of claim 2, wherein the intermediate sensor insulating layer comprises an inorganic material.

6. The display device of claim 2, wherein the intermediate sensor insulating layer comprises an organic material.

7. The display device of claim 1, wherein the display panel comprises a first non-folding area, a folding area, and a second non-folding area, which are arranged in sequence in one direction.

8. The display device of claim 1, wherein the second sensor insulating layer comprises a melamine resin.

9. The display device of claim 1, wherein a thickness of the second sensor insulating layer is in a range of 2.5 times to 4.5 times a thickness of the sensor conductive layer.

10. The display device of claim 1, further comprising an anti-reflective layer on the input sensor and comprising a plurality of color filters and a planarization layer configured to cover the plurality of color filters.

11. The display device of claim 10, wherein the planarization layer comprises a same material as the second sensor insulating layer.

12. The display device of claim 1, wherein the sensor conductive layer is provided as a single layer, and
the second sensor insulating layer is directly on the sensor conductive layer.

13. The display device of claim 1, wherein the display panel comprises:
a display area in which the plurality of pixels are located; and
a peripheral area adjacent to the display area,
wherein the peripheral area comprises a pad area in which a plurality of pads are located,
wherein the second sensor insulating layer comprises a pad opening portion overlapping the pad area.

14. The display device of claim 1, wherein the display panel comprises a first non-bending area, a bending area, and a second non-bending area, which are arranged in sequence in one direction,
wherein the second sensor insulating layer comprises a bending opening portion overlapping the bending area.

15. The display device of claim 1, wherein the display panel comprises:
a pixel defining film in which an emission opening portion is defined;
a light emitting element comprising at least an emission layer in the emission opening portion; and
an encapsulation layer on the light emitting element and the pixel defining film,
wherein the first sensor insulating layer is directly on the encapsulation layer.

16. An electronic device comprising:
a display panel comprising a plurality of pixels;
an input sensor on the display panel; and
a housing accommodates the display panel and the input sensor,
wherein the input sensor comprises:
a first sensor insulating layer on the display panel;
a sensor conductive layer on the first sensor insulating layer and comprising a plurality of conductive patterns;
a second sensor insulating layer directly on the plurality of conductive patterns and comprising a low-temperature curable organic material; and
a protective layer on the second sensor insulating layer.

17. The electronic device of claim 16, wherein a thickness of the second sensor insulating layer is in a range of 2.5 times to 4.5 times a thickness of the sensor conductive layer.

18. A method for manufacturing a display device, the method comprising:
preparing a display panel comprising a plurality of pixels; and
forming an input sensor on the display panel,
wherein the forming of the input sensor comprises:
forming a first sensor insulating layer on the display panel;
forming, on the first sensor insulating layer, a sensor conductive layer comprising a plurality of conductive patterns;
providing an organic composition so as to cover each of the plurality of conductive patterns;
curing the organic composition to form a second sensor insulating layer; and
depositing an inorganic material onto the second sensor insulating layer to form a protective layer.

19. The method of claim 18, further comprising forming, on the input sensor, an anti-reflective layer comprising a plurality of color filters and a planarization layer which covers the plurality of color filters,
wherein the planarization layer is formed of a same material as the organic composition.

20. The method of claim 18, wherein the curing of the organic composition is performed at a temperature of 100° C. or less.
